(19) United States
(12) Patent Application Publication
(10) Pub. No.: US 2026/0265486 A1
(43) Pub. Date: Sep. 10, 2026

(54) NANOPARTICLES INCLUDING QUANTUM DOTS WITHIN MATRICES AND THEIR SYNTHESIS VIA ORGANOMETALLIC PRECURSORS

(71) Applicant: NDSU RESEARCH FOUNDATION, Fargo, ND (US)

(72) Inventors: Philip Boudjouk, Fargo, ND (US); Dean Grier, Fargo, ND (US); Yuvraj Patil, Fargo, ND (US); Tapan Kumar Jena, Ganjam (IN)

(21) Appl. No.: 19/012,377

(22) Filed: Jan. 7, 2025

Related U.S. Application Data
(60) Provisional application No. 63/618,592, filed on Jan. 8, 2024.

(51) Int. Cl. C08K 3/30; C08J 3/215; H10K 85/10; H10K 85/40

(52) U.S. Cl. CPC C08K 3/30; C08J 3/215; H10K 85/10; H10K 85/40; C08J 2383/08; C08K 2003/3009; C08K 2003/3027; C08K 2201/001; C08K 2201/005; C08K 2201/011

(57) ABSTRACT

The disclosure relates to quantum dot (QD) conducting, semiconducting, dielectric, magnetic, magnetoelectric, ferroelectric and/or thermoelectric materials in polymers or network solids. Disclosed are methods for producing nanoparticles in situ in a matrix, through simultaneous pyrolysis or photolysis of an organometallic precursor to nanoparticles with a matrix precursor. Multiple precursors may be combined to provide turning of chemical composition and resultant physical properties.

### CROSS REFERENCE TO RELATED APPLICATIONS

This application claims priority under 35 U.S.C. § 119 to Provisional Application U.S. Ser. No. 63/618,592, filed on Jan. 8, 2024, which is herein incorporated by reference in its entirety including without limitation, the specification, claims, and abstract, as well as any figures, tables, or examples thereof.

### STATEMENT REGARDING FEDERALLY SPONSORED RESEARCH OR DEVELOPMENT

This invention was made with government support under Grant Number N00014-21-1-2969 awarded by the Office of Naval Research. The government has certain rights in the invention.

### TECHNICAL FIELD

The present disclosure relates generally to nanoparticles embedded in matrices. More particularly, the present disclosure relates to quantum dot (QD) conducting, semiconducting, dielectric, magnetic, magnetoelectric, ferroelectric or thermoelectric materials in polymers or network solids. More particularly, but not exclusively, the present disclosure relates to producing nanoparticles in situ in a matrix, through simultaneous pyrolysis or photolysis of an organometallic precursor to nanoparticles with a matrix precursor. Multiple precursors may be combined to provide tuning of chemical composition and resultant physical properties.

### BACKGROUND

The importance of high-quality quantum dots has been increasingly recognized, leading to a dramatic improvement in their performance for various applications. Additionally, the use of semiconducting materials dispersed in polymer matrices has attracted much attention, due to their excellent optical and electronic characteristics compared to their bulk counterparts. Although much progress has been made in the development of polymer nanocomposites, uniform dispersion of nanoparticles remains a challenge. One conventional approach to producing nanocomposites is to first synthesize and isolate QDs, then attempt to disperse them within a polymer.

There is a need in the art of making QD—polymer nanocomposites for single source precursors that allow control over the quantities of dispersed nanoparticles and degrees of dispersion of dispersed nanoparticles within the polymer matrix in order to permit greater management of optoelectronic and thermoelectric properties of these materials.

### BRIEF DESCRIPTION OF THE FIGURES

The following drawings form part of the specification and are included to further demonstrate certain embodiments. In some instances, embodiments can be best understood by referring to the accompanying figures in combination with the detailed description presented herein. The description and accompanying figures may highlight a certain specific example, or a certain embodiment. However, one skilled in the art will understand that portions of the example or embodiment may be used in combination with other examples or embodiments.

FIG. 1 shows x-ray diffractograms at various temperatures showing lead sulfide quantum dots in a nanocomposite.

FIG. 2 shows absorption spectra of nanocomposite films with increasing pyrolysis temperature.

FIG. 3 is a plot of (α*E)² versus energy (E) at varying pyrolysis temperatures.

FIG. 4 is a plot of (α*E)^{1/2} versus energy (E) at varying pyrolysis temperatures.

FIG. 5 is a plot of refractive index versus wavelength for varying pyrolysis temperatures.

FIG. 6 shows the chemical structure of a single source precursor for (Bn₂SnS)₃, (Bn₂SnSe)₃, and (Bn₂SnTe)₃.

FIG. 7 shows the UV-Vis NIR absorption spectra for SnS/siloxane films.

FIG. 8 shows the UV-Vis NIR absorption spectra for SnSe/siloxane films.

FIG. 9 shows the UV-Vis NIR absorption spectra for SnTe/siloxane films.

FIG. 10 shows the direct band gap plots of SnS/siloxane nanocomposite films at varying pyrolysis temperatures.

FIG. 11 shows the indirect band gap plots of SnS/siloxane nanocomposite films at varying pyrolysis temperatures.

FIG. 12 shows the direct band gap plots of SnSe/siloxane nanocomposite films at varying pyrolysis temperatures.

FIG. 13 shows the indirect band gap plots of SnSe/siloxane nanocomposite films at varying pyrolysis temperatures.

FIG. 14 shows the direct band gap plots of SnTe/siloxane nanocomposite films at varying pyrolysis temperatures.

FIG. 15 shows the indirect band gap plots of SnTe/siloxane nanocomposite films at varying pyrolysis temperatures.

FIG. 16 shows a diffractogram for a SnS/siloxane nanocomposite.

FIG. 17 shows a diffractogram for a SnSe/siloxane nanocomposite.

FIG. 18 shows a diffractogram for a SnTe/siloxane nanocomposite.

FIG. 19 is a thermogravimetric plot for (Bn₂SnTe)₃.

FIG. 20 shows powder XRD diffractograms for PbS—SnTe/siloxane nanocomposites.

FIG. 21 shows the UV-Vis absorption spectra of PbS—SnTe/siloxane nanocomposite films at various pyrolysis temperatures.

FIG. 22 shows the direct band gap Tauc plots of PbS—SnTe/siloxane nanocomposite films at various pyrolysis temperatures.

FIG. 23 shows the indirect band gap Tauc plots of PbS—SnTe/siloxane nanocomposite films at various pyrolysis temperatures.

FIG. 24 shows powder XRD diffractograms for SnS—SnSe/siloxane nanocomposites.

FIG. 25 is the same diffractogram as shown in FIG. 24, highlighting the angular progression of diffraction peaks throughout the solid solution series caused by substitution on the chalcogen site.

FIG. 26 shows the UV-Vis absorption spectra of SnS—SnSe/siloxane nanocomposite films at various weight percentages.

FIG. 27 shows the direct band gap plots of SnS—SnSe/siloxane nanocomposite films at various weight percentages.

FIG. 28 shows the indirect band gap plots of SnS—SnSe/siloxane nanocomposite films at various percentages.

FIG. 29 shows powder XRD diffractograms for PbS—SnTe/siloxane nanocomposites.

FIG. 30 shows the UV-Vis absorption spectra of PbS—SnTe/siloxane nanocomposite films at various weight percentages.

FIG. 31 shows the direct band gap Tauc plots of PbS—SnTe/siloxane nanocomposite films at various weight percentages.

FIG. 32 shows the indirect band gap Tauc plots of PbS—SnTe/siloxane nanocomposite films at various percentages.

FIG. 33 shows powder XRD diffractograms for PbS—SnS/siloxane nanocomposites.

FIG. 34 shows the UV-Vis absorption spectra of PbS—SnS/siloxane nanocomposite films at various weight percentages.

FIG. 35 shows the direct band gap Tauc plots of PbS—SnS/siloxane nanocomposite films at various mole percentages.

FIG. 36 shows the indirect band gap Tauc plots of PbS—SnS/siloxane nanocomposite films at various percentages

FIG. 37 shows UV-Vis absorption spectra of CdS/siloxane nanocomposite films at various pyrolysis temperatures.

FIG. 38 shows the direct band gap Tauc plots of CdS/siloxane nanocomposites at various pyrolysis temperatures.

FIG. 39 shows the indirect band gap Tauc plots of CdS/siloxane nanocomposite films at various pyrolysis temperatures.

FIG. 40 shows powder XRD diffractograms for PbS—CdS/siloxane nanocomposites.

FIG. 41 shows the UV-Vis absorption spectra of PbS—CdS/siloxane nanocomposite films at various weight percentages.

FIG. 42 shows the direct band gap Tauc plots of PbS—CdS/siloxane nanocomposite films at various compositional percentages.

FIG. 43 shows the indirect band gap Tauc plots of PbS—CdS/siloxane nanocomposite films at various percentages.

FIG. 44 shows an x-ray diffractogram of SnSe in amorphous Si, pyrolyzed at 200° C.

### DETAILED DESCRIPTION

The present disclosure is not to be limited to that described herein. Mechanical, electrical, chemical, procedural, and/or other changes can be made without departing from the spirit and scope of the present disclosure. No features shown or described are essential to permit basic operation of the present disclosure unless otherwise indicated. Unless defined otherwise, all technical and scientific terms used above have the same meaning as commonly understood by one of ordinary skill in the art to which embodiments of the present disclosure pertain.

Numeric ranges recited within the specification are inclusive of the numbers defining the range and include each integer and/or real number within the defined range. Throughout this disclosure, various aspects of this invention are presented in a range format. It should be understood that the description in range format is merely for convenience and brevity and should not be construed as an inflexible limitation on the scope of the invention. Accordingly, the description of a range should be considered to have specifically disclosed all the possible sub-ranges, fractions, and individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6, and decimals and fractions, for example, 1.2, 3.8, 1′₂, and 4%. This applies regardless of the breadth of the range.

### Definitions

So that the present invention may be more readily understood, certain terms are first defined. Unless defined otherwise, all technical and scientific terms used herein have the same meaning as commonly understood by one of ordinary skill in the art to which embodiments of the invention pertain. Many methods and materials similar, modified, or equivalent to those described herein can be used in the practice of the embodiments of the present invention without undue experimentation, the preferred materials and methods are described herein. In describing and claiming the embodiments of the present invention, the following terminology will be used in accordance with the definitions set out below.

The terms “a,” “an,” and “the” include both singular and plural referents.

The term “or” is synonymous with “and/or” and means any one member or combination of members of a particular list.

As used herein, the term “exemplary” refers to an example, an instance, or an illustration, and does not indicate a most preferred embodiment unless otherwise stated.

The term “about,” as used herein, refers to variation in the numerical quantity that can occur, for example, through typical measuring techniques and equipment, with respect to any quantifiable variable, including, but not limited to, concentration, mass, volume, time, temperature, density, size (including, but not limited to diameter, average diameter, and aspect ratio), direct band gap (represented by Eg/d (eV)), indirect band gap (represented by Eg/id (eV)), or other quantifiable variables disclosed herein. Further, solid and liquid handling procedures used in the real world can generate certain inadvertent error and variation that is likely through differences in the manufacture, source, or purity of the ingredients used to make the compositions or carry out the methods and the like. The term “about” also encompasses these variations. Whether or not modified by the term “about,” the claims include equivalents to the quantities.

As used herein, “DI” refers to deionized. For example, DI water refers to deionized water.

As used herein, “rpm” refers to revolutions per minute.

As used herein, “curing” refers to the transition of the physical state of a polymer precursor to form a polymeric material, including, but not limited to a matrix. Suitable curing techniques include but are not limited to rapid mixing, photolysis, and thermolysis.

As used herein, “photolysis” refers to decomposition of a material by the action of light.

As used herein, “thermolysis” refers to decomposition of a material at an elevated temperature. It may also be referred to as pyrolysis or annealing.

Unless otherwise specified, the term “alkyl” includes both “unsubstituted alkyls” and “substituted alkyls.” As used herein, the term “substituted alkyls” refers to alkyl groups having substituents replacing one or more hydrogens on one or more carbons of the hydrocarbon group. Such substituents may include, for example, alkenyl, alkynyl, halogeno, hydroxyl, alkylcarbonyloxy, arylcarbonyloxy, alkoxycarbonyloxy, aryloxy, aryloxycarbonyloxy, carboxylate, alkylcarbonyl, arylcarbonyl, alkoxycarbonyl, aminocarbonyl, alkylaminocarbonyl, dialkylaminocarbonyl, alkylthiocarbonyl, alkoxyl, phosphate, phosphonato, phosphinato, cyano, amino (including alkyl amino, dialkylamino, arylamino, diarylamino, and alkylarylamino), acylamino (including alkylcarbonylamino, arylcarbonylamino, carbamoyl and ureido), imino, sulfhydryl, alkylthio, arylthio, thiocarboxylate, sulfates, alkylsulfinyl, sulfonates, sulfamoyl, sulfonamido, alkylselenyl, selenolates, selenamoyl, selnenamide, nitro, trifluoromethyl, cyano, azido, heterocyclic, alkylaryl, or aromatic (including heteroaromatic) groups.

As used herein, “direct band gap” is represented by Eg/d (eV).

As used herein, “indirect band gap” is represented by Eg/id (eV).

As used herein, “nanoparticle” refers to a material having at least one dimension of a size less than 1000 nm. Nanoparticles is inclusive of quantum dots as used herein; however, it should be understood that many materials qualifying as nanoparticles (e.g., having a dimension of 100 nms) do not qualify as quantum dots.

As used herein “Bn” denotes a benzyl group, “Bh” denotes a benzyhydryl group, and “Tt” denotes a trityl group.

References to elements herein are intended to encompass any or all of their oxidative states and isotopes. For example, discussion of silicon can include Si⁻⁴, Si⁻³, Si⁻², Si⁻¹, Si¹, Si², Si³, or Si⁴ and any of its isotopes, e.g., ²⁸Si, ²⁹Si, and ³⁰Si.

The term “substantially” refers to a great or significant extent. “Substantially” can thus refer to a plurality, majority, and/or a supermajority of said quantifiable variables, given proper context.

The terms “weight percent,” “wt. %,” “wt-%,” “percent by weight,” “% by weight,” and variations thereof, as used herein, refer to the concentration of a substance as the weight of that substance divided by the total weight of the composition and multiplied by 100.

As referred to herein, “substantially homogeneous” refers to a material that is substantially uniform or has substantially the same properties throughout. For example, a mixture in which a material is completely dissolved in a solvent or is uniform under visual inspection, such that a material having multiple components evenly distributed throughout the material (e.g., a solution comprising two or more solvents evenly distributed throughout the solution).

The term “configured” describes structure capable of performing a task or adopting a particular configuration. The term “configured” can be used interchangeably with other similar phrases, such as constructed, arranged, adapted, manufactured, and the like.

Terms characterizing sequential order, a position, and/or an orientation are not limiting and are only referenced according to the views presented.

The methods and compositions of the present invention may comprise, consist essentially of, or consist of the components and ingredients of the present invention as well as other ingredients described herein. As used herein, “consisting essentially of” means that the methods, systems, apparatuses and compositions may include additional steps, components or ingredients, but only if the additional steps, components or ingredients do not materially alter the basic and novel characteristics of the claimed methods, systems, apparatuses, and compositions.

The “invention” is not intended to refer to any single embodiment of the particular invention but to encompass all possible embodiments as described in the specification and the claims. The “scope” of the present disclosure is defined by the appended claims, along with the full scope of equivalents to which such claims are entitled. The scope of the disclosure is further qualified as including any possible modification to any of the aspects and/or embodiments disclosed herein which would result in other embodiments, combinations, subcombinations, or the like that would be obvious to those skilled in the art.

### Composites Comprising Nanoparticles, Including Quantum Dots

Disclosed herein are composites comprising nanoparticles. The composites and nanoparticles disclosed herein provide improvements over those traditionally prepared. This is in part because of the ability to tailor the properties of the nanoparticles in the composite. Properties which can be tailored include, but are not limited to, the nanoparticle size, direct band gap energy, indirect band gap energy, refractive index, and dispersion of the nanoparticles. Further, because the ratio of nanoparticle precursor to matrix precursor can be controlled, and because these precursors are intimately mixed in solution, the nanoparticle spatial distribution and loading within the matrix can similarly be tailored within the matrix. Via the methods disclosed herein, the quantum dot size distribution and loading can be tailored; further, the specific density of the composite can be tailored as well based on the quantum dot tailoring.

Preferably, the nanoparticles are uniformly dispersed within the matrix.

Preferably, the nanoparticles have a size less than about 500 nm, less than about 450 nm, less than about 400 nm, less than about 350 nm, less than about 300 nm, less than about 250 nm, less than about 200 nm, less than about 190 nm, less than about 180 nm, less than about 170 nm, less than about 160 nm, less than about 150 nm, less than about 140 nm, less than about 130 nm, less than about 120 nm, less than about 110 nm, less than about 100 nm, less than about 95 nm, less than about 90 nm, less than about 85 nm, less than about 80 nm, less than about 75 nm, less than about 70 nm, less than about 65 nm, less than about 60 nm, less than about 55 nm, less than about 50 nm, less than about 45 nm, less than about 40 nm, less than about 35 nm, less than about 30 nm, less than about 25 nm, less than about 24 nm, less than about 23 nm, less than about 22 nm, less than about 21 nm, less than about 20 nm, less than about 19 nm, less than about 18 nm, less than about 17 nm, less than about 16 nm, less than about 15 nm, less than about 14 nm, less than about 13 nm, less than about 12 nm, less than about 11 nm, or less than about 10 nm. Preferably, the nanoparticles have a size greater than about 1 nm up to about 500 nm; more preferably from about 1.1 nm to about 50 nm, from 1.1 nm to about 40 nm, from about 1.1 nm to about 35 nm, from about 1.2 nm to about 30 nm, from about 1.3 nm to about 25 nm, from about 1.4 nm to about 20 nm, from about 1.5 nm to about 15 nm. Most preferably, the nanoparticles have a tailored size of less than the Bohr radii of the nanoparticles' constituents as measured by x-ray diffraction. The average nanoparticle diameter can be measured via a suitable methodology; as described herein, a preferred methodology is by powder x-ray diffraction (XRD). High resolution transmission electron microscopy (TEM) is also effective to measure particle size, as well as to determine morphology, aspect ratio, and size and spatial distribution. Small angle X-ray scattering, field-flow fractionation, analytical ultracentrifugation, and optical absorption techniques are also used to determine nanoparticle size distribution. Monodispersity is defined as the coefficient of variation, or relative standard deviation (RSD) divided by the mean particle size: RSD=σ/xₘₑₐₙ, where RSD<0.5. Preferred variance is such that RSD<0.1, which constitutes “narrow” particle size distribution.

Preferably the nanoparticles have a direct band gap energy between about 1.6 and about 5.2 Eg/d (eV).

Preferably the nanoparticles have an indirect band gap energy between about 0.2 and about 5.0 Eg/id (eV).

The nanoparticles preferably comprise an alkali or alkaline earth metal, a metalloid, transition metal, post-transition metal, main group element, or combinations thereof. Preferred quantum dots comprise one or more of the following Li, Na, K, Rb, Cs, Be, Mg, Ca, Sr, Ba, Ti, Zr, Hf, V, Mo, W, Zn, Hg, Th, B, Al, Ga, Si, Ge, Sn, Pb, As, Bi, Cd, Cu, In, P, S, Sb, Se, Te, GeS, GeSe, GeTe, SnS, SnSe, SnTe, PbS, PbSe, PbTe, CdS, CdSe, CdTe, ZnS, ZnSe, ZnTe, InP, InAs, GaAs, Bi₂S₃, Bi₂Se₃, Bi₂Te₃, Sb₂S₃, Sb₂Se₃, Sb₂Te₃, CuInSe₂, inorganic perovskites of the formulas ABX₃, A₂BX₆, A₂M^{I}M^{III}X₆, A₂M^{I}M^{III}X₈, A₂YX, A₃BX₆ or A₃B₂X₉ where A=Cs, Rb, K, and/or a lanthanide, B/M^{I}M^{III}=Pb, Sn, Mn, Fe, Co, Ni, Zn, Bi, Sb, Mo, W, Ru, Rh, Cu, Ag, and/or B, X=₀, S, Se, Te, F, Cl, Br, and/or I, Y=S, Se, and/or Te, with or without doping of transition metals such as Mn, Co, Fe, and/or Ni, a combination thereof and/or a solid solution of the foregoing.

As described further herein, the nanoparticles are dispersed within a polymeric or network solid matrix. The matrix can comprise an oligomer, a polymer, a copolymer, a terpolymer, an “x”omer, a network solid, or a combination thereof. Additionally, the matrix can further comprise an inorganic material, an organic material, or a mixture thereof.

Preferably, the matrix precursor comprises one or more compounds that are polyheterocycles (including but not limited to, polythiophenes, polypyrazines, and/or polypyrroles), siloxanes (including polysiloxanes), polypropylenes, polyethylenes, polyanilines, polyphenylenes, polyacetylenes, polystyrenes, acrylates (including, but not limited to, methacrylate and/or polyacrylates), polyphenols, epoxides, peptides, polypeptides, peptoids, cellulose, silanes, silicene, germanes, germanene, 2 dimensional forms of silicon oxide, germanium oxide, tin oxide, and lead oxide, graphite, including reduced-dimension forms such as graphene and graphene oxide, or combinations or mixtures thereof.

The “matrix” is a polymeric material and/or network solid formed by the matrix precursor and the curing. Within the matrix can be the nanoparticles, such that the combination of nanoparticles and matrix form a “nanocomposite.”

The matrix can be in an amount of from about 5 wt. % to about 99 wt. % of the composite, more preferably from about 51 wt. % to about 98 wt. %, more preferably from about 52 wt. % to about 97 wt. %, more preferably from about 53 wt. % to about 96 wt. %, more preferably from about 54 wt. % to about 95 wt. %.

Functional side-groups on polymeric matrix precursors may be attached as necessary to, for example, improve solubility and/or provide capping agents for the quantum dot surfaces. Preferred functional side-groups are organic moieties, which preferably can comprise one or more of a thiol, a phosphine, an alkyl, an alkene, a carboxylic acid, an aromatic group, a hetero-atom cyclic group, TOPO, an ether, an ester, or a combination thereof. The organic material can be in an amount of from about 0.1 wt. % to about 95 wt. % of the composite. During curing it is possible that the functional side-groups on the matrix precursors are lost or transformed into other groups.

Network solid matrices may comprise a polysilane, silicon (amorphous, polycrystalline, doped or undoped by hydrogen or other dopants), germanium (amorphous, polycrystalline, doped or undoped by hydrogen or other dopants), or combination thereof. Additionally, network solid matrices may be comprised of the quantum dot compositions.

The composites can be prepared as thick composite films, thin composite films or ultra-thin composite films, which can be layered and/or added to a substrate. If layered, different composites can be utilized for each layer to provide different physical properties. Preferably, a thick film has a nominal thickness of from about 1 micrometer to about 1000 micrometers. Preferably, a thin film or ultra thin film has a nominal film thickness of from about 0.5 nm to about 100 nm, more preferably from about 0.7 nm to about 75 nm.

The composites comprising quantum dots can be used in a variety of electronic devices and are not limited by the type of electronic device, which may include but are not limited to, phones, tablets, computers, wearables, sensors, chips, electronic displays, batteries, electronic printing devices, energy storage devices, materials for energy production, magnetoelectronic devices, magnetic devices, photovoltaic devices, and solar cells, including Quantum Dot Solar Cells (QDSCs) and Intermediate Band Solar Cells (IBSCs).

### Methods of Forming the Nanocomposite

Disclosed herein are methods for producing nanoparticles in situ in a polymer, through simultaneous thermolysis or photolysis of an organometallic precursor to nanoparticles with a matrix precursor. Generally, the method comprises mixing a precursor of the nanoparticles and a precursor of the matrix and subjecting that mixture to thermolysis or photolysis to produce the nanoparticles in situ and disperse them uniformly throughout the matrix. One or more nanoparticle precursors may be used. Without being limited to any specific mechanism or theory, the precursor undergoes decomposition and/or polymerization coincident to decomposition of the nanoparticle precursor, forming the nanocomposite of nanoparticles within a matrix.

The method of forming the nanocomposite as described herein comprises combining at least one single source organometallic precursor and a matrix precursor into a substantially homogeneous solution to mix the precursors at the molecular level, removing the solvent as necessary, and then subjecting that solution to thermolysis and/or photolysis. If utilizing thermolysis, preferably the solvent is removed from a cast film to form a residual solid mixture, and then the residual solid mixture is heated. If utilizing photolysis, the solvent can be removed or remain (in a preferred embodiment, the solvent remains) and the solution is exposed to light waves to initiate the photolytic reaction.

Suitable solvents include, but are not limited to, aqueous solvents (including water), organic solvents (including, but not limited to, alcohols, linear, branched, or cyclic alkanes, ketones, tetrahydrofuran, chlorinated methanes, toluene, pyridine, dimethylformamide, dimethylsulfoxide, ethyl acetate, acetonitrile, and mixtures thereof), and mixtures thereof. More preferably, organic solvents include, but are not limited to, linear, branched or cyclic C 5-30 alkanes; linear, branched or cyclic C 5-30 alkenes; linear, branched or cyclic C 5-30 alkynes; linear or cyclic poly (dimethylsilane); aromatic C 6-20 hydrocarbons; and mixtures thereof. Even more preferably, at least a second solvent is selected from the group consisting of linear, branched or cyclic C 5-16 alkenes; toluene; xylene; mesitylene; hexamethyldisiloxane; or mixtures thereof. Most preferably, at least a second solvent is selected from the group consisting of linear C 7-11 alkanes, such as heptane, octane, nonane, decane and undecane, and mixtures thereof. Further examples of suitable solvents, include, but are not limited to, water and aliphatic, alicyclic or aromatic hydrocarbons, such as, for example, petroleum ether, hexane, heptane, cyclohexane, methylcyclohexane, benzene, toluene, xylene or decalin; halogenated hydrocarbons such as, for example, chlorobenzene, dichlorobenzene, dichloromethane, chloroform, carbon tetrachloride, dichloroethane or trichloroethane; alcohols such as methanol, ethanol, n- or iso-propanol, n-, iso-, sec- or tert-butanol, ethanediol, propane-1,2-diol, ethoxyethanol, methoxyethanol, diethylene glycol monomethyl ether, dimethyl ether diethylene glycol; acetonitrile, N-methyl-2-pyrrolidone (NMP), dimethylformamide (DMF), dimethyl sulfoxide (DMSO), N, N-dimethylacetamide, nitromethane, nitrobenzene, hexamethylphosphoramide (NMRT), 1,3-dimethyl-2-imidazolidinone (DMI) 1,3-dimethyl-3,4,5,6-tetrahydro-2 (1H)-pyrimidinone (DMPU), ethyl acetate, acetone, butanone; esters such as diethyl ether, diisopropyl ether, methyl tert-butyl ether, methyl tert-amyl ether, dioxane, tetrahydrofuran, 1,2-dimethoxyethane, 1,2-diethoxyethane or anisole; and mixtures thereof.

In an embodiment, the method comprises thermolysis. In an embodiment, the thermolysis comprises heating the mixture of precursors to a temperature of at least about 100° C., at least about 120° C., at least about 150° C., at least about 200° C., at least about 250° C., at least about 300° C., at least about 350° C., at least about 500° C., at least about 750° C., at least about 1000° C., at least about 1200° C., at least about 1400° C., at least about 1600° C., or up to about 1800° C. In an embodiment the thermolysis comprises heating the mixture to the set temperature for at least about 15 min, at least about 20 min, or at least about 30 min. In an embodiment, the thermolysis comprises heating the mixture to the set temperature for about 15 min to about 45 min, or for about 30 min. In an embodiment, the thermolysis comprises ramping up to the set temperature at a rate of about 50° C. per min.

In an embodiment, the matrix precursor comprises siloxane (Si—O—Si) functional groups. In an embodiment, the matrix precursor comprises a siloxane polymer. In an embodiment, the matrix precursor comprises mercaptopropylmethylpolysiloxane. In an embodiment the matrix precursor comprises benzylmercaptopropylmethylpolysiloxane. In an embodiment, the matrix precursor comprises mercaptopropylmethylpolysiloxane and benzylmercaptopropylmethylpolysiloxane. In an embodiment, the matrix precursor comprises mercaptopropylmethylpolysiloxane and benzylmercaptopropylmethylpolysiloxane in a weight ratio of mercaptopropylmethylpolysiloxane to benzylmercaptopropylmethylpolysiloxane of about 1:4 to about 4:1, or of about 1:1. In an embodiment, the matrix precursor comprises a polymer, a copolymer, an inorganic material, a functional side-group, or a combination thereof.

In an embodiment, the precursor of the QDs comprises an organometallic precursor. In a preferred embodiment, the organometallic precursor comprises a precursor of a metal chalcogenide. In an embodiment, the organometallic precursor comprises a phenyl, a benzyl, a benzyhydryl, a trityl, and/or an allyl leaving group. In an embodiment, the organometallic precursor comprises (Bn₂GeSe)₃, Bn₃Bi, Bn₃Sb, Bn₃In, (PhSe)₂Pb, (BnS)₃Bi, Pb(SBn)₂, (Bn₂SnS)₃, (Bn₂SnSe)₃, (Bn₂SnTe)₃, Cd(SBn)₂, (Bn₂GeS)₃, (Bn₂GeTe)₂, or a mixture thereof.

In an embodiment, the method comprises dissolving the organometallic precursor in an organic solvent prior to combining the organometallic precursor with the matrix precursor. In an embodiment, the method comprises dissolving the matrix precursor in an organic solvent prior to combining the matrix precursor and the organometallic precursor. In an embodiment, the method comprises more than one organometallic precursor, wherein the organometallic precursors are dissolved into a solvent to form a single solution comprising all organometallic precursors, and then combining that solution with the matrix precursor. In an embodiment, the organic solvent comprises tetrahydrofuran, pyridine, dichloromethane, or a combination thereof. In an embodiment, the organic solvent is chosen based on solubility and reactivity of the specific organometallic precursor. In an embodiment, tetrahydrofuran (THF) is used for a tin selenide-based precursor. In an embodiment, pyridine is used for a tin sulfide-based precursor. In an embodiment, dichloromethane is used for a tin telluride-based precursor. In an embodiment, pyridine is used for a lead sulfide-based precursor.

In an embodiment, pryidine is used for a cadmium sulfide-based precursor.

In an embodiment, the mixture of an organometallic precursor with a matrix precursor comprises Pb(SBn)₂ and siloxane polymer, the thermolysis is at a temperature of about 150° C. to about 350° C. In an embodiment, the organometallic precursor comprises (Bn₂SnS)₃ and siloxane polymer, the thermolyzing is at a temperature of about 200° C. to about 350° C. In an embodiment, the organometallic precursor comprises (Bn₂SnSe)₃ and siloxane polymer, the thermolysis is at a temperature of about 200° C. to about 350° C. In an embodiment, the organometallic precursor comprises (Bn₂SnTe)₃ and a siloxane polymer, and the thermolyzing is at a temperature of about 120° C. to about 350° C. In an embodiment, the organometallic precursor comprises Cd(SBn)₂ and a siloxane polymer, and the thermolyzing is at a temperature of about 250° C. to about 300° C. This example embodiment demonstrates how the nanoparticle materials can be prepared in a matrix by mixing an organometallic precursor and matrix precursor and subjecting the materials to thermolysis.

In an embodiment, the method comprises at least two organometallic precursors. In an embodiment, the at least two organometallic precursors comprise (Bn₂SnS)₃ and (Bn₂SnSe)₃. In an embodiment, the at least two organometallic precursors comprise Pb(SBn)₂ and (Bn₂SnS)₃. In an embodiment, the at least two organometallic precursors comprise Pb(SBn)₂ and Cd(SBn)₂. In an embodiment, the at least two organometallic precursors comprise Pb(SBn)₂ and (Bn₂SnTe)₃. In any embodiment comprising two organometallic precursors, the two precursors may be in a weight ratio of from about 1:0 to about 0:1, or from about 4:1 to about 1:4, or from about 1:3 to about 3:1.

In an embodiment, the thermolysis temperature is selected based on desired electrical and/or physical properties of the resultant nanocomposite. In an embodiment the ratio of nanoparticle precursor to matrix precursor and thermolysis temperature and heating time are selected to procure a specific density, nanoparticle size, and/or band gap energy, of the resultant nanocomposite.

Materials with low band gaps can absorb photons with lower energy levels which can absorb a broader range of wavelengths, including those in the infrared region, which is important for applications like photovoltaics and photodetectors. These materials effectively convert solar energy into electricity. The Shockley-Queisser limit is the theoretical maximum efficiency of a single-junction solar cell under ideal conditions, which is around 33.7%, with band gap 1.4 eV. So, achieving a band gap near 1.4 eV is useful strategy for achieving highly efficient materials for solar cells. Alternatively, strategies for absorbing multiple ranges of wavelengths, such as those used in Intermediate Band Solar Cells, may require a higher band gap (e.g., 1.95 eV), with two or more intermediate bands of lower gaps.

### EXAMPLES

Embodiments of the present disclosure are further defined in the following non-limiting Examples. It should be understood that these Examples, while indicating certain embodiments of the disclosure, are given by way of illustration only. From the above discussion and these Examples, one skilled in the art can ascertain the essential characteristics of this disclosure, and without departing from the spirit and scope thereof, can make various changes and modifications of the embodiments of the disclosure to adapt it to various usages and conditions. Thus, various modifications of the embodiments of the disclosure, in addition to those shown and described herein, will be apparent to those skilled in the art from the foregoing description. Such modifications are also intended to fall within the scope of the appended claims.

### Materials and Evaluation Methods:

Reagents were used as purchased without further purification.

Solvents were purified, including drying, according to accepted standard procedures, as necessary.

X-ray diffraction data were collected on a Rigaku MiniFlex 6G, using Cu Kα (1.54056 Å) radiation, line focus, low angle direct beam stop, 2.5° incident beam Soller slits, 10 mm axial divergence mask, 0.6250 incident beam fixed divergence (beam height) slit, Anton-Paar BTS 500 sample stage with knife edge, Ni K0 filter, 0.8 mm scatter slit, 2.5° diffracted beam Soller slits, and a D/TeX 1D detector. Diffractograms were collected from 10-100° 20, with a 0.01° step size at 2°/min.

Optical data were collected on a Cary 5000 UV-Vis-NIR spectrophotometer, in the wavelength range from 200-1500 nm.

### Example 1—Synthesis and Characterization of PbS/Siloxane Polymer-Based Nanocomposites with Varying Formation Temperatures

A Pb(SBn)₂ single source precursor was prepared as follows, and according to scheme (1). 20 mL distilled water, 60 mL ethanol, and a magnetic stir bar were added to a 250 mL 3-neck flask fitted with an addition funnel, a reflux condenser, and stopper. This solution was sparged with nitrogen for 1 hr, followed by addition of 2.002 g (5.28 mmol) of Pb(OAc)₂, which produced a clear, colorless solution. After heating for 1 hr at 60° C., 1.2 mL (10.2 mmol) of benzylmercaptan was added. The solution immediately precipitated a yellow powder in suspension. The suspension was heated for an additional 30 min and then allowed to cool to ambient temperature. Following filtration through a glass frit, the yellow powder was transferred to a 50 mL round bottomed flask, and heated under vacuum overnight to dry, producing a 95.10% yield of Pb(SBn)₂ powder.

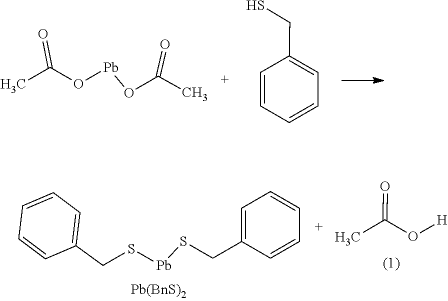

A siloxane polymer was prepared as follows, and according to scheme (2). 4.674 g (34.8 mmol) of mercaptopropylmethylpolysiloxane (MPMS), 4.808 g (34.8 mmol) K₂CO₃and 20 mL acetone were added to a 100 mL round bottom flask. The resulting suspension was stirred at 0° C. for 30 min. A 2.0 mL (2.201 g, 17.4 mmol) aliquot of benzyl chloride was added and stirred for an additional 30 min. The suspension was filtered into a second 100 mL round bottom flask. The residue was rinsed with acetone and the filtrate evaporated, producing a clear, pale yellow, viscous liquid product at 60% yield. 100 mL ethyl acetate, the product, and 100 mL 0.1N HCl was added to a 250 mL separatory funnel. The organic fraction was extracted, and a second extraction was performed with another 20 mL of ethyl acetate. The extracted fractions were combined, dried with sodium sulfate, filtered, evaporated, and dried at 80° C. under vacuum, producing 50 mol. % mercaptopropylmethylpolysiloxane and 50 mol. % benzylmercaptopropylmethylpolysiloxane.

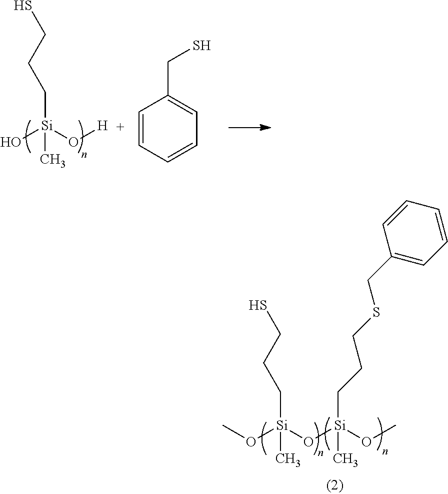

Nanocomposite thin films were prepared as follows. An aliquot of 50 mg of the siloxane polymer was stirred with 1.5 mL of pyridine for 30 min in a vial to dissolve. In another vial, 50 mg of Pb(SBn)₂ was separately stirred into 0.5 mL pyridine for 5 min. Once dissolved, the solutions of organometallic precursors and siloxane were stirred together for an additional 5 min, producing a clear, pale yellow solution.

Quartz discs 15 mm in diameter and 1 mm thick were rinsed with acetone and DI water. A portion of the clear, pale yellow solution was added dropwise onto each disc and spin cast for 10 sec at 1,000 RPM and an additional 20 sec at 2,500 RPM.

The resulting films were placed into a custom fabricated sample holder, then added to the chamber of an Anton-Paar BTS 500 heated stage. The chamber was evacuated for 5 min, followed by heating. Heating ramp rates were 50° C. per min, followed by holding for 30 min at temperature, then returning to 30° C. before collecting x-ray diffractograms in situ. The samples were heated to temperatures of 150° C., 200° C., 250° C., or 350° C.

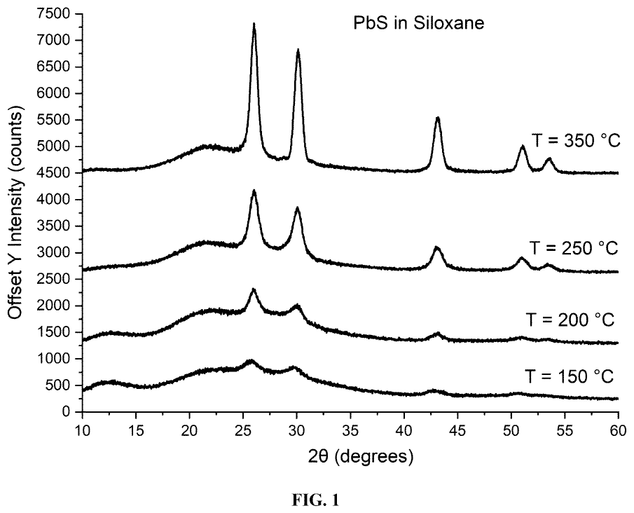

Powder x-ray diffractograms of the spin cast thin films are shown in FIG. 1. The crystalline peaks are due to PbS. The broad diffuse scattering maximum near 20° 20 in each diffractogram is due to the quartz disc film support. Average crystallite size of PbS nanoparticles is shown in Table 1. X-ray diffraction characterization showed lead sulfide quantum dots in the nanocomposite. No other reflections were observed, indicating phase purity.

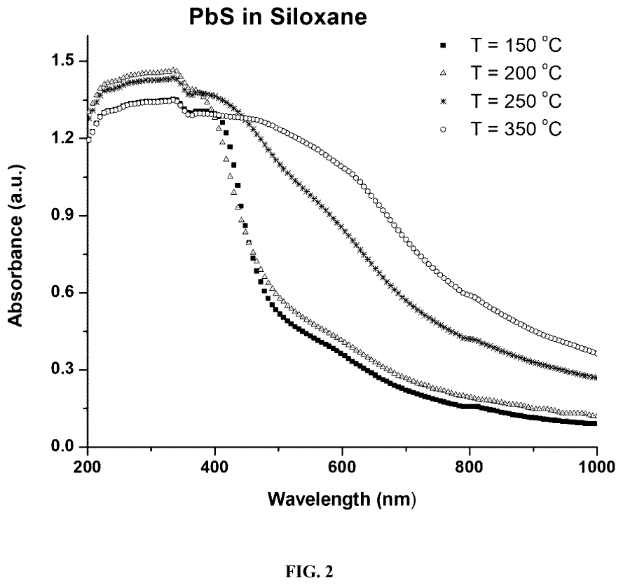

The absorption data of the nanocomposite films were recorded at room temperature to understand the absorption behavior and to calculate the band gap energy. The absorption spectra of nanocomposite films with increasing pyrolysis temperature are shown in FIG. 2. FIG. 2 shows intense absorption in the ultraviolet region at 150° C. and 200° C., whereas at 250° C., and 350° C. additional bands above 400 nm were observed. The red shift in absorption of PbS observed correlates with the increase in the PbS particle size.

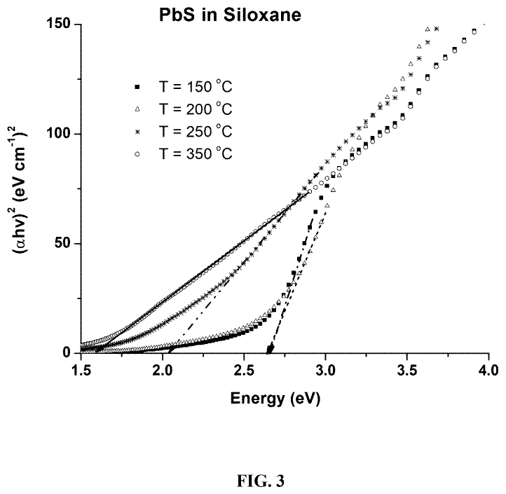

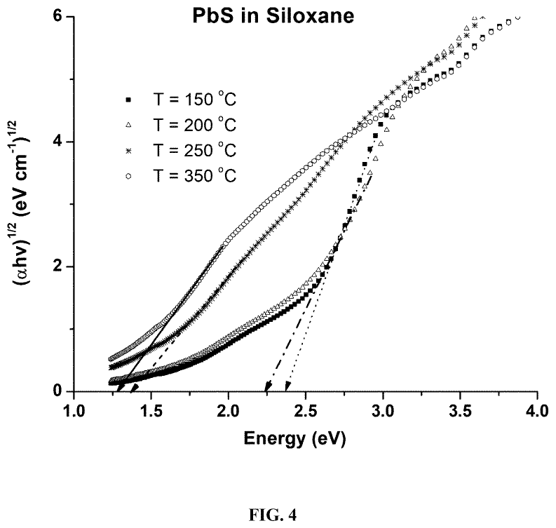

The minimum energy needed to transfer an electron from the valence band to the conduction band in a semiconductor is known as the band gap energy. At fixed values of momentum, the energy difference between two bands is called the direct band gap whereas indirect band gap energy is the difference when the momentum values are different. This energy gap is very important in the field of photonics since it determines how energy from a photon can be used to generate an electron-hole pair. Direct and indirect optical band gaps for the PbS/siloxane nanocomposites were determined from the absorption data near the edges, using the Tauc Equation (3). Plotting (α*E)² versus energy (E) and (α*E)^{1/2} versus energy (E) give estimates of the direct (Eg/d) and indirect energy gaps (Eg/id) as shown in FIG. 3 and FIG. 4, respectively, and in Table 1. Band gap varied inversely with temperature and nanoparticle size. Optical band gaps in the PbS/siloxane nanocomposites (Table 1) are all higher than that of the bulk PbS value (0.41 eV) due to the quantum confinement effect in nanocomposites.

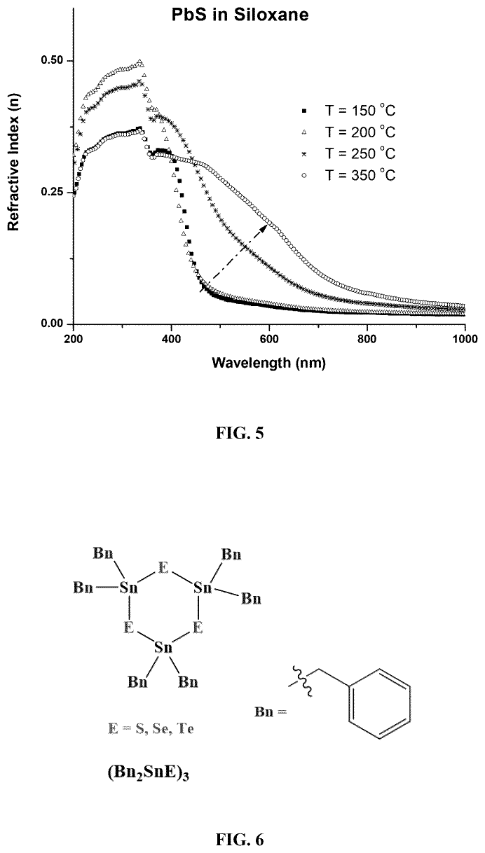

With increasing temperature, significant changes in refractive index of the film were observed (see FIG. 5), coincident with decomposition and removal of organic residues. While refractive index is an inherent property of individual materials, this observed change in refractive index may accompany an increasing proportion of PbS nanoparticles in the films. As shown in FIG. 5, with the increase of pyrolysis temperature from 200° C. to 250° C., a new band in the visible to NIR wavelength region arises due to an increase in the particle size and to the increasing relative content of PbS in the film.

UV-Vis spectra displayed broad absorption bands covering the UV-Vis to NIR region corresponding to PbS quantum dots. The optical band gap, determined from UV-Vis absorption using Tauc plots, decreased from 2.66 eV to 1.29 eV with an increase in pyrolysis temperature from 150° C. to 350′C. Trends in blue shifts in the UV-Vis absorption, decreases in the refractive indices and increases in bandgaps relative to bulk PbS are also correlated with decreasing nanoparticle size. The results demonstrate that particle size and associated properties can be controlled by the temperature used in thermolysis. XRD analysis showed that the average size of nanoparticles at 150° C., 200′C, 250′C, and 350′C is between 4 and 11 nm, demonstrating a quantum dot size regime for all pyrolysis temperatures, and that with increasing temperature, the particle size increased.

### Example 2—Synthesis and Characterization of SnS/, SnSe, and SnTe Siloxane Polymer-Based Nanocomposites with Varying Formation Temperatures

Single source precursors of (Bn₂SnS)₃, (Bn₂SnSe)₃, and (Bn₂SnTe)₃ were prepared according to literature procedures, including, Boudjouk, P., Seidler, D. J., Grier, D., McCarthy, G. J. Benzyl-substituted tin chalcogenides. Efficient single-source precursors for tin sulfide, tin selenide, and Sn(SxSel-x) solid solutions. Chem. Mater. 1996, 8, 1189-1196 (hereinafter; “Boudjouk, 1996”). and Boudjouk, P., Remington, M. P., Grier, D. G., Triebold, W., Jarabek, B. R. 2,2,4,4,6,6-Hexabenzylcyclotristannatellurane, (Bn2SnTe)3. Synthesis and Structural Characterization of an Organometallic Single-Source Precursor to Phase-Pure, Polycrystalline SnTe. Organometallics 1999, 18, 4534-4537. The chemical structures of these single source precursors are shown in FIG. 6. A siloxane polymer was prepared as described in Example 1.

The siloxane polymer (50 mg) was stirred with 1.5 mL of solvent for 30 min in a vial to dissolve. In another vial, 50 mg of organometallic single source tin chalcogenide precursor was stirred into 0.5 mL solvent for 5 min. Once dissolved, the solutions of organometallic precursors and siloxane were mixed and stirred together for an additional 15 min, producing a uniform solution. Different solvents were used for the film preparation on the basis of solubility and reactivity of precursors. Tetrahydrofuran was used for the tin selenide-based precursor, pyridine was used for the tin sulfide-based precursor, and dichloromethane was used for the tin telluride-based precursor.

Quartz discs 15 mm in diameter and 1.5 mm thick were rinsed with acetone and DI water. Solutions were added dropwise onto the discs and spin cast for 10 sec at 1,000 RPM and an additional 20 sec at 2,500 RPM. Tin telluride is a good absorber and scatters X-rays effectively, thus thin films work well for data collection. However, scattering in the case of tin sulfide and tin selenide is low. To increase the amount of material available for strong X-ray diffraction signals without producing films too opaque for optical measurements, additional drops were added to the spin cast films and the solvent was allowed to evaporate.

The quartz discs coated with cast films were placed onto quartz slides. The slides and discs were inserted into a tube furnace. Nitrogen was passed through the furnace for 5 min at 8 scfm to flush the chamber. The nitrogen flow was reduced to 1-2 bubbles per second as observed in a bubbler at the outlet, and heating was started. The furnace temperature was ramped over 30 min from ambient to the target temperatures, followed by holding for 30 min at those temperatures, then returning to 30° C. before collecting X-ray diffractograms and UV-Vis spectra.

For SnS nanocomposites, residual unpyrolyzed crystalline organometallic precursor was observed by XRD after pyrolysis at 150° C. and 200° C. Crystalline phases observed after pyrolysis at 250° C. and 300° C. are a mix of cubic (π) and orthorhombic (a) SnS. For SnSe nanocomposites, the crystalline phase following pyrolysis at 150° C. is orthorhombic (a) SnSe, while the crystalline phases after pyrolysis at 200° C., 250° C., and 300° C. are a mix of cubic (π) and orthorhombic (α) SnSe. For SnTe, the sole crystalline phase after pyrolysis at 120° C., 150° C., and 200° C. is cubic SnTe, while crystalline phases after pyrolysis at 250° C. and 300° C. are cubic SnTe with traces of Te.

The average particle sizes of the nanoparticles in the SnS/siloxane, SnSe/siloxane, and SnTe/siloxane nanocomposite films, heated to various temperatures, are shown in Table 1. The particle sizes observed by XRD indicate that quantum dot-sized particles were obtained in the case of tin selenide (7.5-10.1 nm) and tin telluride (53-89 nm). These sizes are significantly smaller than their respective exciton Bohr radii (18 nm for SnSe and 95 nm for SnTe). The particle sizes obtained from the XRD of tin sulfide were between 32-35 nm, which is larger than its Bohr radius (3-5 nm).

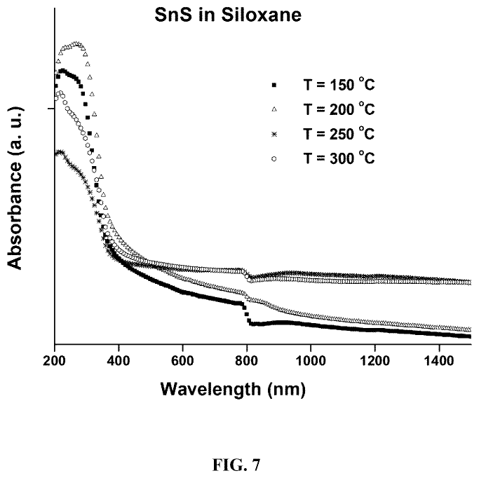

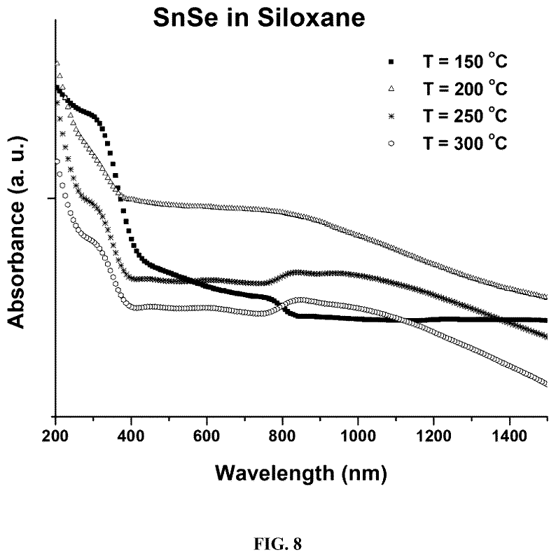

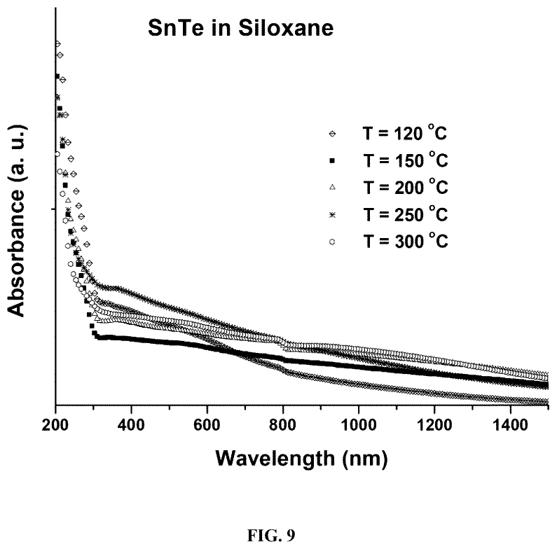

The UV-Vis spectra in FIG. 7, FIG. 8, and FIG. 9 show the absorption behavior of the nanocomposite films of SnS/siloxane, SnSe/siloxane, and SnTe/siloxane, respectively, obtained at different temperatures. The absorption spectra were recorded at room temperature to determine the absorption behavior and to calculate the band gap energies. The optical properties of these materials are crucial for their potential applications in optoelectronic devices, such as solar cells, light-emitting diodes, and photodetectors. Absorption edges were shifted toward higher wavelengths (lower energy) with increasing temperatures, indicating related decreases in the band gaps of the materials.

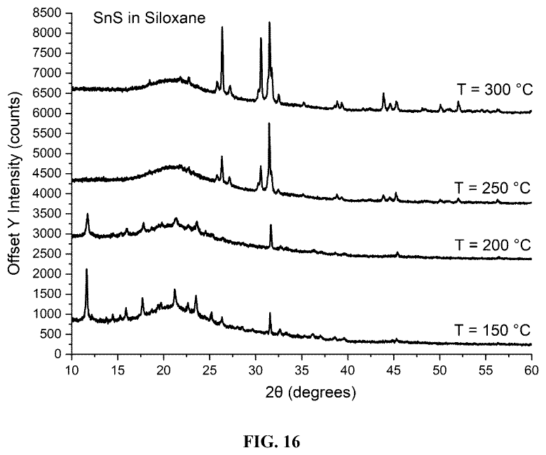

Intense absorption bands were observed in the UV region tailing into the Vis region in all three tin chalcogenide nanocomposites, as shown in FIGS. 7-9. The UV-Vis-NIR absorption spectra of SnS/siloxane films in FIG. 7 show an onset of absorbance increase located at about 830 nm for the nanocomposite films heated to temperatures of 250° C. and 300° C. The direct band gap for bulk SnS is 1.3 eV, hence an absorption onset of 954 nm would be expected in the absence of quantum confinement effects. The absorbance increase near 830 nm was not observed for nanocomposite films pyrolyzed at 150° C. or 200° C. In these films the precursor molecules had not decomposed to SnS. The diffractogram for the SnS/siloxane nanocomposite (FIG. 16) verified the presence of residual (Bn₂SnS)₃ precursor material and the absence of crystalline SnS.

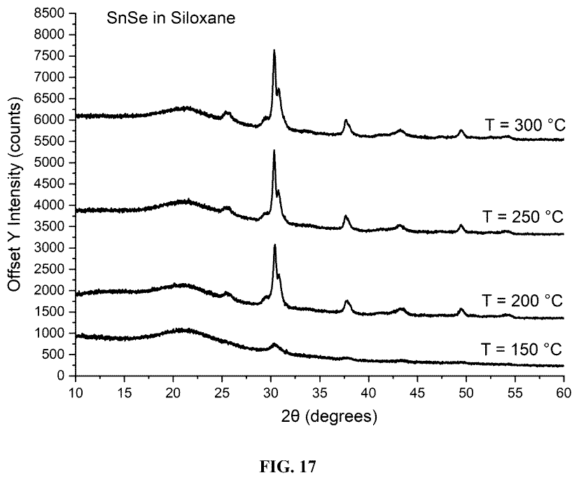

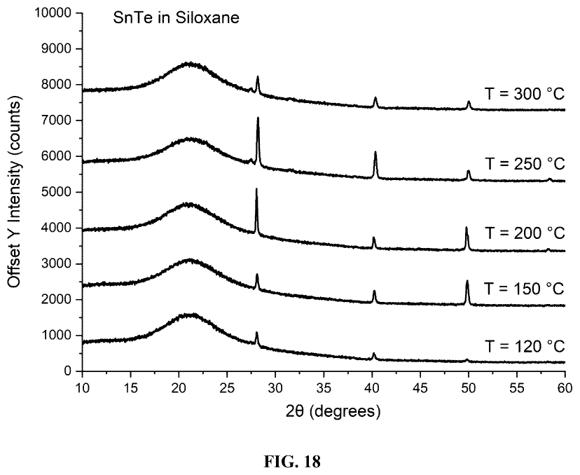

FIG. 8 shows the absorption behavior of SnSe/siloxane films in the UV-Vis-NIR region. The diffractogram (FIG. 17) shows decomposition to SnSe for the nanocomposite films beginning at 200° C. Nanocomposite films heated at 150° C. exhibit the presence of intense bands around 300 nm and the absence of bands above the visible region. These observations indicate the residual presence of the precursor, (Bn₂SnSe)₃, and absence of the decomposition product SnSe in the film pyrolyzed at 150° C., confirmed in FIG. 8 wherein only starting precursor absorbance bands are observed.

FIG. 9 shows the absorption behavior of SnTe/siloxane films at various temperatures. The low intensity bands observed in the UV-Vis-NIR region were due to the presence of SnTe for all the temperatures ranging from 120° C. to 300° C. The absence of absorbance bands from the precursor in the UV region indicates complete decomposition at temperatures as low as 120° C.

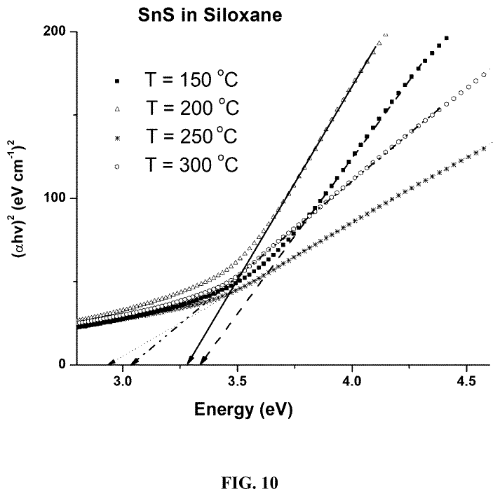

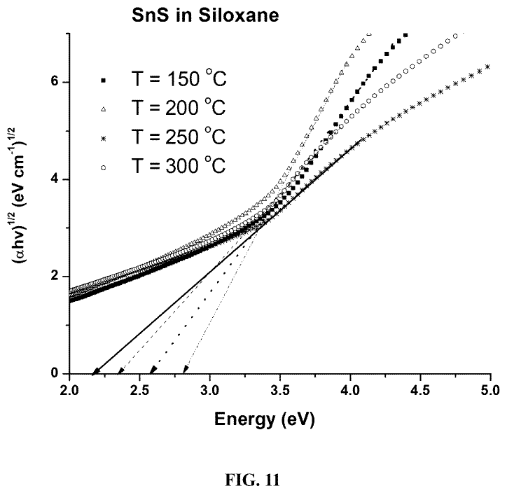

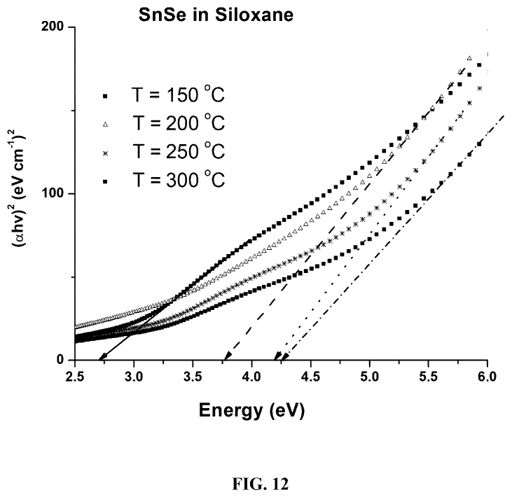

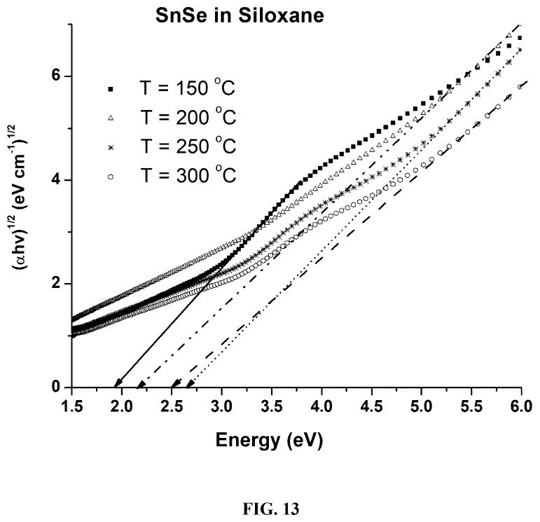

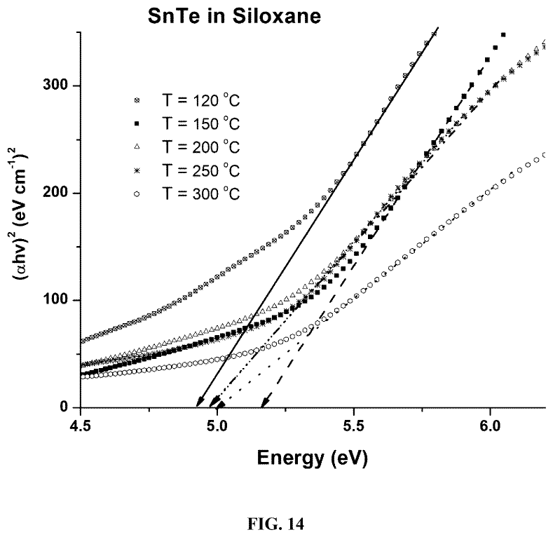

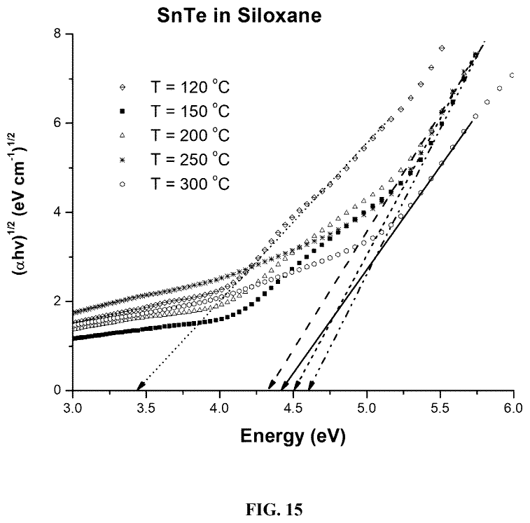

The direct and indirect band gap plots of SnS/siloxane nanocomposite films at varying temperatures are shown in FIG. 10 and FIG. 11. The direct and indirect band gap plots of SnSe/siloxane nanocomposite films at varying temperatures are shown in FIG. 12 and FIG. 13. The direct and indirect band gap plots of SnTe/siloxane nanocomposite films at varying temperatures are shown in FIG. 14 and FIG. 15. The results are also shown in Table 1. The bandgap energies of the nanocomposites vary with temperature and chalcogen element (Table 1). Band gap values for SnS/siloxane films lie in the range of 2.17 eV to 3.04 eV, 1.94 eV to 4.26 eV for SnSe/siloxane, and 3.44 eV to 5.17 eV for SnTe/siloxane films. The band gap values for bulk SnSe, SnS, and SnTe are 0.98 eV, 1.3 eV, and 0.18 eV, respectively.

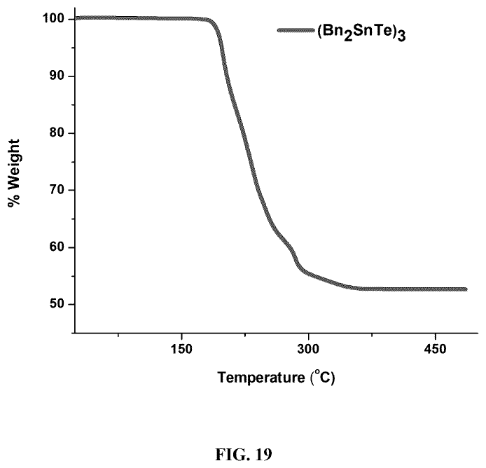

The thermogravimetric plot for (Bn₂SnTe)₃, is shown in FIG. 19, indicating a decomposition temperature at around 192° C., with no significant loss of mass above about 275° C.

The results herein indicate that a broad temperature range is available for these binary metal chalcogenides to work in making quantum dots. The results further demonstrate that the co-pyrolysis temperatures for SnS/, SnSe/, and SnTe/siloxane nanocomposites are lower compared to those for bulk/pure metal combinations. Tin chalcogenide quantum dot nanocomposites made with a siloxane polymer offer a vast potential for designing new materials with promising properties for a wide range of electronic and photovoltaic applications.

### Example 3—Synthesis and Evaluation of Binary CdS/Siloxane Polymer-Based Nanocomposite with Varying Formation Temperatures

Cd(SBn)₂precursors were prepared according to literature procedures (Resta, V.; Laera, A. M.; Piscopiello, E.; Schioppa, M.; Tapfer, L. Highly efficient precursors for direct synthesis of tailored CdS nanocrystals in organic polymers. J. Phys. Chem. C 2010, 114 (41), 17311-17317.) A siloxane polymer was prepared according to the method described in Example 1.

Polymer nanocomposite thin films were prepared as follows. An aliquot of 20 mg of the siloxane polymer was stirred with 1.5 mL of pyridine for 30 min in a vial to dissolve. In another vial, 20 mg of Cd(SBn)₂ was separately stirred into 0.5 mL pyridine for 5 min. Once dissolved, the solutions of organometallic precursors and siloxane were stirred together for an additional 5 min.

Quartz discs 15 mm in diameter and 1.5 mm thick were rinsed with acetone and DI water. A portion of the solution was added dropwise onto each disc and spin cast for 10 sec at 1,000 RPM and an additional 20 sec at 2,500 RPM. To increase the amount of material available for strong X-ray diffraction signals without producing films too opaque for optical measurements, additional drops were added to the spin cast films and the solvent was allowed to evaporate.

The quartz discs coated with cast films were placed onto quartz slides. The slides and discs were inserted into a tube furnace. A purge of nitrogen was passed through the furnace for 5 min at 8 scfm. The nitrogen flow was reduced to a minimal flow observed as 1-2 bubbles per second in an exhaust bubbler and heating was started. The furnace temperature was ramped to the target temperatures over 30 min, followed by holding for 30 min, then returning to 30° C. before collecting X-ray diffractograms. The effects of variation of precursor weight compositions in the nanocomposites on nanoparticle size and optical properties were studied using powder X-ray diffraction and UV-Vis absorption spectroscopy techniques respectively.

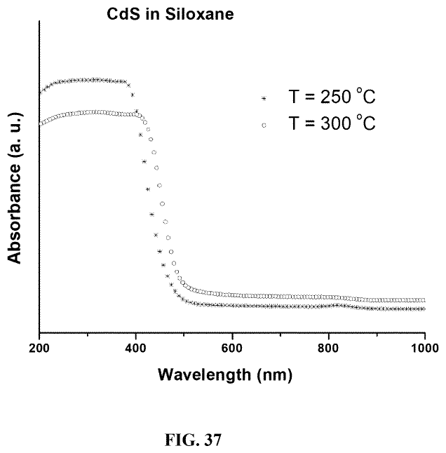

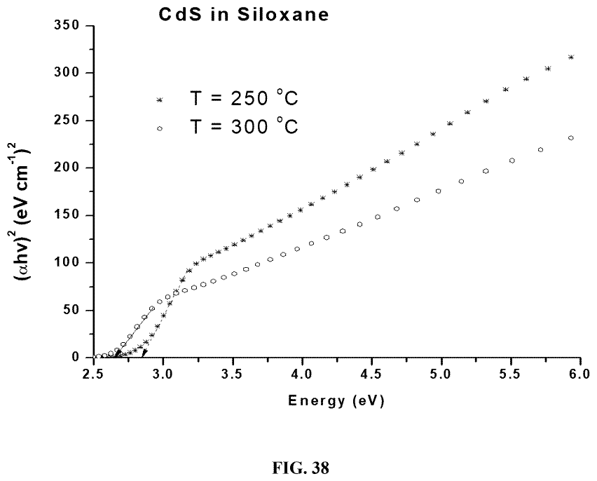

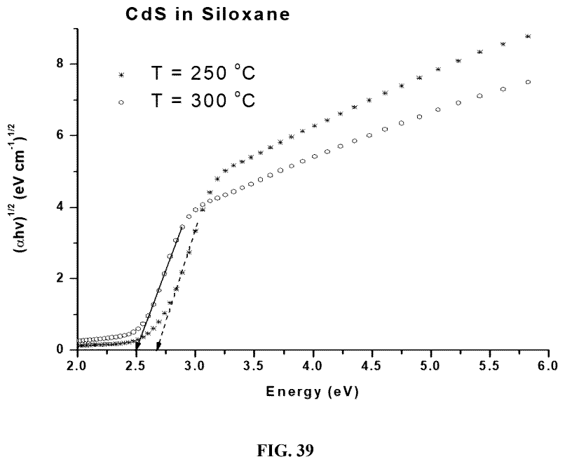

UV-Vis absorption spectra of CdS/siloxane nanocomposite films at various temperatures are shown in FIG. 37. The CdS/siloxane nanocomposites gave absorption bands spanning the UV-Vis region, ranging from 200 nm to 500 nm. A slight red shift was observed in the absorption spectra for the film pyrolyzed at 300° C. relative to that at 250° C. This shift can be attributed to a small increase in the particle sizes of the CdS quantum dots, which measured 1.6 nm at 250° C. and 1.8 nm at 300° C. FIG. 38 shows the direct band gap Tauc plots of CdS/siloxane nanocomposites at various temperatures. FIG. 39 shows the indirect band gap Tauc plots of CdS/siloxane nanocomposite films at various temperatures. Band gaps ranged from 2.50 eV to 2.85 eV, which are red-shifted relative to the band gap of bulk CdS at approximately 2.4 eV.

### Example 4—Synthesis and Characterization of Ternary SnS—SnSe Siloxane Polymer-Based Nanocomposites with Varying Compositional Ratios

Single source organometallic precursors (Bn₂SnS)₃ and (Bn₂SnSe)₃ were prepared according to literature methods, including, Boudjouk, 1996, Chemistry of Materials. A siloxane polymer was prepared according to the methods described in Example 1.

An aliquot of 20 mg of siloxane polymer was stirred with 1.5 mL of pyridine for 30 min in a vial to dissolve. In another vial, 20 mg total mass of organometallic single source precursor with various weight percentages were dissolved in pyridine and stirred for 10 min. The weight percent ratios of (Bn₂SnS)₃ and (Bn₂SnSe)₃ to each other were 100:00, 75:25, 50:50, 25:75 and 00:100. Once dissolved, the solutions of organometallic precursors and siloxane were mixed and stirred together for an additional 15 min.

Quartz discs 15 mm in diameter and 1.5 mm thick were rinsed with acetone and DI water. Solutions were added dropwise onto the discs and spin cast for 10 sec at 1,000 RPM and an additional 20 sec at 2,500 RPM. To increase the amount of material available for strong XRD signals without producing films too opaque for optical measurements, additional drops were added to the spin cast films and the solvent was allowed to evaporate.

The quartz discs coated with cast films were placed onto quartz slides. The slides and discs were inserted into a tube furnace. A purge of nitrogen was passed through the furnace for 5 min at 8 scfm. The nitrogen flow was reduced to a minimal flow observed as 1-2 bubbles per second in an exhaust bubbler and heating was started. The furnace temperature was ramped to a target temperature of 250° C. over 30 min, followed by holding for 30 min, then returning to 30° C. before collecting X-ray diffractograms. The effects of variation of precursor weight compositions in the nanocomposites on nanoparticle size and optical properties were studied using powder X-ray diffraction and UV-Vis absorption spectroscopy techniques respectively.

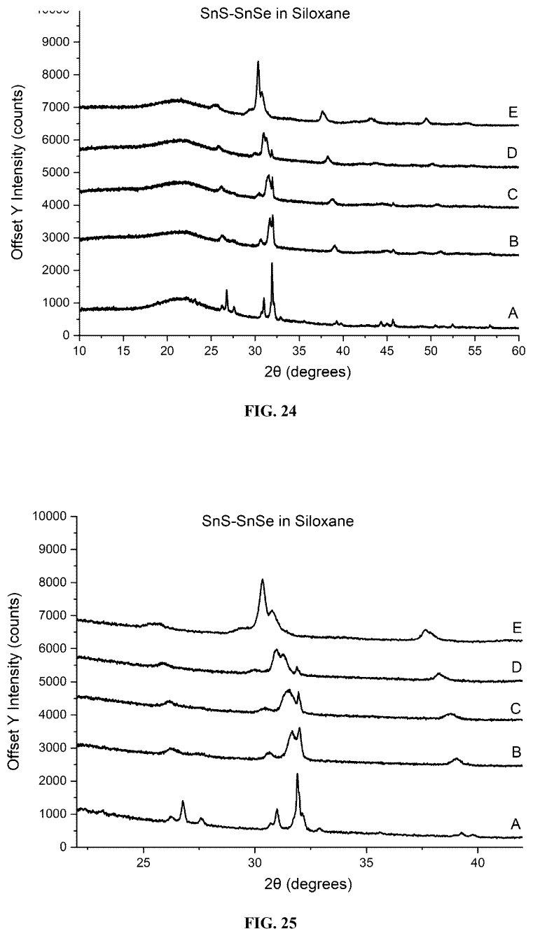

Powder XRD diffractograms for the SnS—SnSe/siloxane nanocomposites are shown in FIG. 24. Weight ratios of SnS and SnSe precursors are given in mg:mg, with the corresponding molar composition of product Sn(SₓSe₁₋ₓ): A=20:0 (x=1), 15:5 (x=0.77), B=10:10 (x=0.53), C=5:15 (x=0.28), E=0:20 (x=0). Powder XRD patterns were taken at 30° C. Crystalline peaks are due to Sn(SₓSe₁₋ₓ) phases. The broad diffuse scattering maxima near 20° 20 are due to the quartz discs supporting the films. FIG. 25 is the same diffractogram but highlighting the angular progression of diffraction peaks throughout the solid solution series caused by substitution on the chalcogen site. The crystalline phases in materials A-D are a mixture of cubic (π) SnS and orthorhombic (α) Sn(SₓSe₁₋ₓ). Material E has a mixture of cubic (π) SnSe and orthorhombic (α) SnSe. As highlighted in FIG. 25, XRD reflections shift from higher to lower 20 angles (lower to higher d-spacings and associated lattice parameters of orthorhombic α-Sn(SₓSe₁₋ₓ)), as the percent of SnS is decreased relative to SnSe. Note the unvarying position of the cubic (π) SnS peak near 34° 20 in all but the top (E, SnSe) plot.

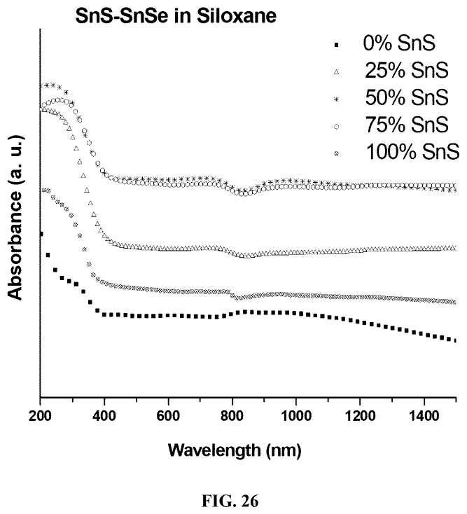

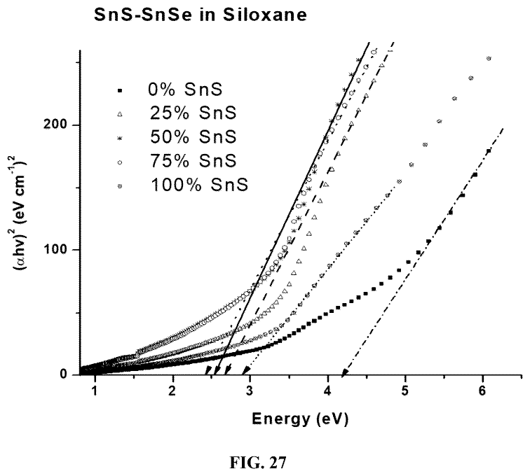

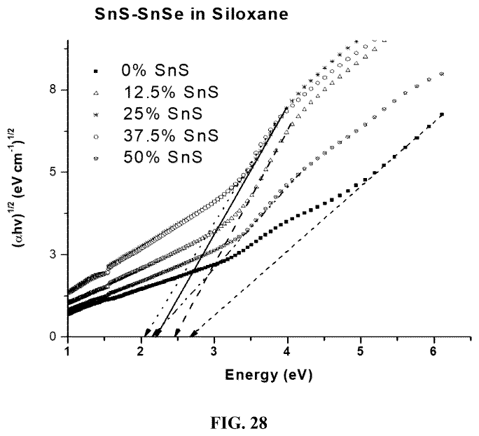

FIG. 26 shows the UV-Vis absorption spectra of the SnS—SnSe/siloxane nanocomposite films at various weight percentages. FIG. 27 shows the direct band gap plots of SnS—SnSe/siloxane nanocomposite films at various weight percentages. FIG. 28 shows the indirect band gap plots of SnS—SnSe/siloxane nanocomposite films at various percentages.

The particle sizes obtained by XRD indicate that in the intermediate compositions, quantum dot-sized particles were produced for all but the nanoparticulate Sn(S_{0.75}Se_{0.25}). The exciton Bohr radii of SnS and SnSe are (3-5 nm) and 18 nm respectively. UV-Vis spectra displayed broad absorption bands covering the UV-Vis-NIR region with optical band gaps of the intermediates ranging from 2.05 to 2.69 eV.

### Example 5—Synthesis and Evaluation of Ternary PbS—SnS Siloxane Polymer-Based Nanocomposite with Varying Compositional Ratios

Pb(SBn)₂ and (Bn₂SnS)₃ precursors and siloxane polymer were prepared according to the methods described in Examples 1 and 2.

An aliquot of approximately 20 mg of siloxane polymer was stirred with 1.5 mL of organic solvent pyridine for 30 min in a vial to dissolve. In another vial, a sum total of approximately 20 mg of (Bn₂SnS)₃ and Pb(SBn)₂ single source precursors were mixed in various mole percentages according to the desired inorganic semiconductor product composition, dissolved in pyridine, and stirred for 10 min. The molar ratios of mixed Pb(SBn)₂ and (Bn₂SnS)₃ precursors were 0:1, 0.25:0.75, 0.5:0.5, 0.75:0.25, and 1:0. Once dissolved, the solutions of organometallic precursors and siloxane were mixed and stirred together for an additional 15 min.

Quartz discs 15 mm in diameter and 1.5 mm thick were rinsed with acetone and DI water. Solutions were added dropwise onto the discs and spin cast for 10 sec at 1,000 RPM and an additional 20 sec at 2,500 RPM. To increase the amount of material available for strong XRD signals without producing films too opaque for optical measurements, additional drops were added to the spin cast films and the solvent was allowed to evaporate.

The quartz discs coated with cast films were placed onto quartz slides. The slides and discs were inserted into a tube furnace. A purge of nitrogen was passed through the furnace for 5 min at 8 scfm. The nitrogen flow was reduced to a minimal flow observed as 1-2 bubbles per second in an exhaust bubbler and heating was started. The furnace temperature was ramped to a target temperature of 250° C. over 30 min, followed by holding for 30 min, then returning to 30° C. before collecting X-ray diffractograms. The effects of variation of precursor molar compositions in the nanocomposites on nanoparticle size and optical properties were studied using powder X-ray diffraction and UV-Vis absorption spectroscopy techniques respectively.

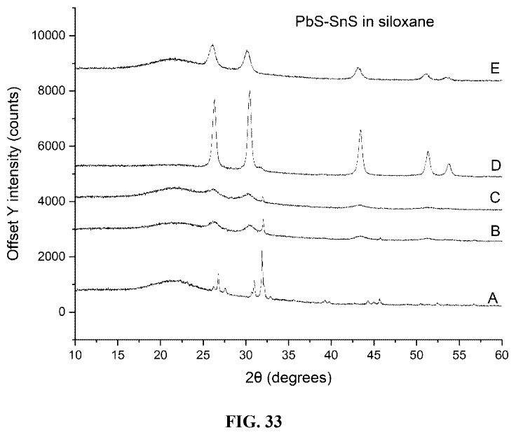

Powder XRD diffractograms for the PbS—SnS/siloxane nanocomposites are shown in FIG. 33. The Pb(SBn)₂ and (Bn₂SnS)₃ precursors were mixed according to the following target PbS:SnS molar ratios of the pyrolyzed nanoparticles: A=0:1, B=0.25:0.75, C=0.5:0.5, D=0.75:0.25, E=1:0. Crystalline peaks in A were due to SnS phases. A single SnS peak was also visible near 32° 20 in B through D. Broad peaks in B through E are due to PbS. The broad diffuse scattering maxima near 20° 20 are due to the quartz discs supporting the films.

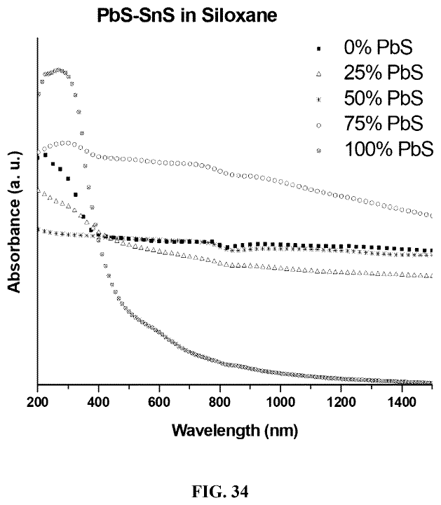

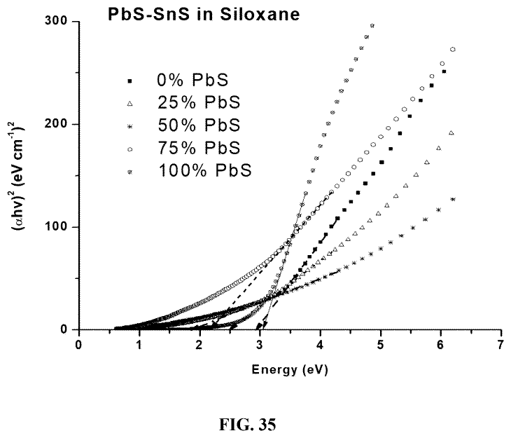

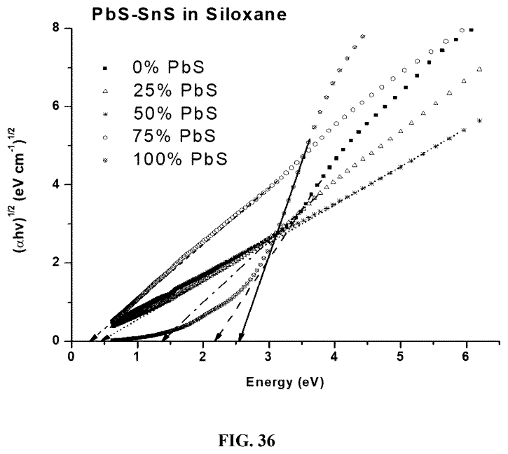

FIG. 34 shows the UV-Vis absorption spectra of the PbS—SnS/siloxane nanocomposite films at various weight percentages. The PbS—SnS/siloxane absorption spectra show absorption bands in the UV-NIR region. The pure SnS/siloxane nanocomposite has intense absorption bands spanning the UV-Vis region, ranging from 200 nm to 500 nm. With increasing PbS content in the nanocomposites, a bathochromic shift in absorption span is observed with absorption bands tailing towards the NIR region (above 800 nm). FIG. 35 shows the direct band gap Tauc plots of PbS—SnS/siloxane nanocomposite films at various mole percentages. FIG. 36 shows the indirect band gap Tauc plots of PbS—SnS/siloxane nanocomposite films at various percentages. Intermediate compositional members of the ternary nanocomposite system PbS—SnS show direct band gaps varying between 1.87 and 2.5 eV, and indirect band gaps ranging from 0.27 to 1.38 eV.

### Example 6—Synthesis and Evaluation of Ternary PbS—CdS/Siloxane Polymer-Based Nanocomposites with Varying Compositional Ratios

Pb(SBn)₂ and Cd(SBn)₂ precursors and a siloxane polymer were prepared according to the methods described in Examples 1 and 3.

An aliquot of approximately 20 mg of the siloxane polymer was stirred with 1.5 mL of pyridine for 30 min in a vial to dissolve. In another vial, a sum total of approximately 20 mg of Pb(SBn)₂ and Cd(SBn)₂ single source precursors with various weight percentages (corresponding to the desired molar ratios of the pyrolyzed nanoparticulate compositions) were dissolved in pyridine and stirred for 10 min. The ratios of the Pb(SBn)₂ and Cd(SBn)₂ precursors were set to correspond to resulting nanocomposite PbS:CdS molar ratios of 1:0, 0.75:0.25, 0.50:0.50, 0.25:0.75, and 0:1. Once dissolved, the solutions of organometallic precursors and siloxane were mixed and stirred together for an additional 15 min.

Quartz discs 15 mm in diameter and 1.5 mm thick were rinsed with acetone and DI water. Solutions were added dropwise onto the discs and spin cast for 10 sec at 1,000 RPM and an additional 20 sec at 2,500 RPM. To increase the amount of material available for strong XRD signals without producing films too opaque for optical measurements, additional drops were added to the spin cast films and the solvent was allowed to evaporate.

The quartz discs coated with cast films were placed onto quartz slides. The slides and discs were inserted into a tube furnace. A purge of nitrogen was passed through the furnace for 5 min at 8 scfm. The nitrogen flow was reduced to a minimal flow observed as 1-2 bubbles per second in an exhaust bubbler and heating was started. The furnace temperature was ramped to a target temperature of 250° C. over 30 min, followed by holding for 30 min, then returning to 30° C. before collecting X-ray diffractograms. The effects of variation of precursor weight compositions in the nanocomposites on nanoparticle size and optical properties were studied using powder X-ray diffraction and UV-Vis absorption spectroscopy techniques respectively.

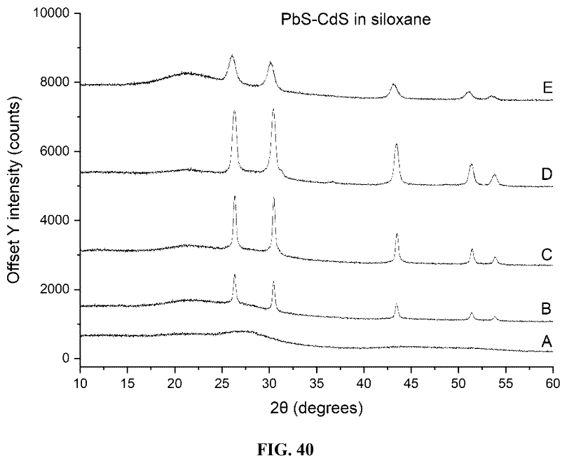

Powder XRD diffractograms for this system are shown in FIG. 40. Molar ratios of Pb(SBn)₂ and Cd(SBn)₂: A=0:1, B=0.25:0.75, C=0.5:0.5, D=0.75:0.25, E=1:0. Very broad, diffuse peaks due to CdS are visible in A and less apparent in B through D, with the major peak of CdS occurring between the first two peaks of PbS. Broad crystalline peaks in B through E are due to PbS. The broad diffuse scattering maxima near 20° 20 are due to the quartz discs supporting the films.

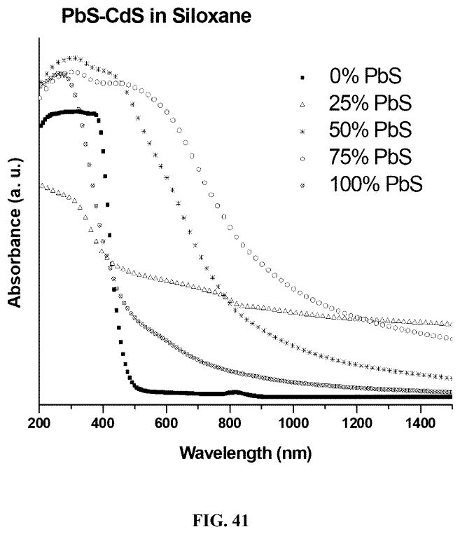

FIG. 41 shows the UV-Vis absorption spectra of the PbS—CdS/siloxane nanocomposite films at various weight percentages. In nanocomposites of PbS—CdS/siloxane, we observed broad absorption bands in the UV-NIR region. Intense absorption bands span the UV-Vis region, ranging from 200 nm to 500 nm in the nanocomposite of pure CdS/siloxane. Increasing PbS content in the nanocomposites is accompanied by a bathochromic shift in absorption bands tailing towards the NIR region (above 800 nm).

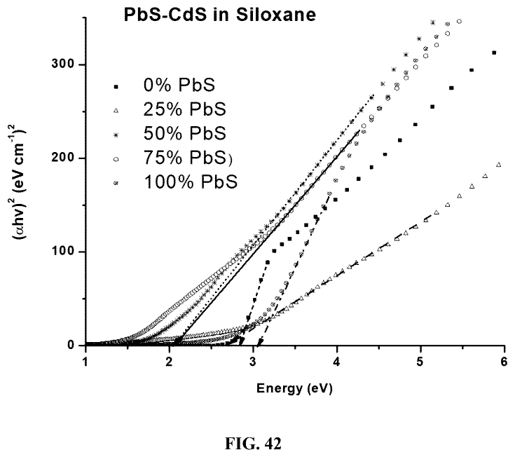

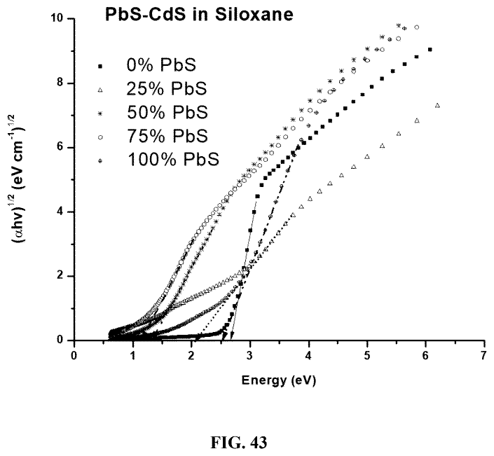

FIG. 42 shows the direct band gap Tauc plots of PbS—CdS/siloxane nanocomposite films at various compositional percentages. FIG. 43 shows the indirect band gap Tauc plots of PbS—CdS/siloxane nanocomposite films at various percentages. Intermediate compositional members of the PbS—CdS nanocomposite system show direct band gaps in the 2.03 to 2.71 eV range. Indirect band gaps range from 1.16 to 2.06 eV.

### Example 7—Synthesis and Evaluation of Quaternary PbS—SnTe Siloxane Polymer-Based Nanocomposite with Varying Compositional Ratios

Pb(SBn)₂ and (Bn₂SnTe)₃ precursors and a siloxane polymer were prepared according to the methods described in Examples 1 and 2.

An aliquot of 20 mg of siloxane polymer was stirred with 1.5 mL of pyridine for 30 min in a vial to dissolve. In another vial, 20 mg of (Bn₂SnTe)₃ and Pb(SBn)₂ organometallic single source precursors with various weight percentages were dissolved in pyridine and stirred for 10 min. The weight ratios of Pb(SBn)₂ and (Bn₂SnTe)₃ precursors were 1:0, 0.75:0.25, 0.50:0.50, 0.25:0.75, and 0:1, with corresponding molar ratios of the organometallic precursors equal to 1:0, 0.74:0.26, 0.49:0.51, 0.24:0.76, and 0:1. Once dissolved, the solutions of organometallic precursors and siloxane were mixed and stirred together for an additional 15 min.

Quartz discs 15 mm in diameter and 1.5 mm thick were rinsed with acetone and DI water. Solutions were added dropwise onto the discs and spin cast for 10 sec at 1,000 RPM and an additional 20 sec at 2,500 RPM. To increase the amount of material available for strong XRD signals without producing films too opaque for optical measurements, additional drops were added to the spin cast films and the solvent was allowed to evaporate.

The quartz discs coated with cast films were placed onto quartz slides. The slides and discs were inserted into a tube furnace. A purge of nitrogen was passed through the furnace for 5 min at 8 scfm. The nitrogen flow was reduced to a minimal flow observed as 1-2 bubbles per second in an exhaust bubbler and heating was started. The furnace temperature was ramped to a target temperature of 250° C. over 30 min, followed by holding for 30 min, then returning to 30° C. before collecting X-ray diffractograms. The effects of variation of precursor weight compositions in the nanocomposites on nanoparticle size and optical properties were studied using powder X-ray diffraction and UV-Vis absorption spectroscopy techniques respectively.

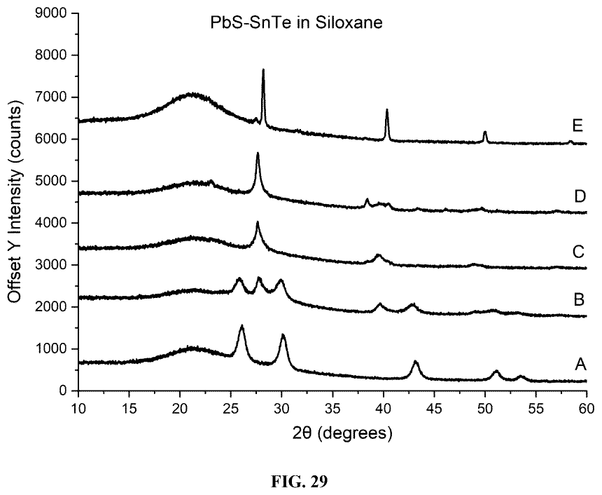

Powder XRD diffractograms for this system are shown in FIG. 29. Weight ratios of PbS and SnTe precursors are given in mg:mg, with corresponding molar composition of product (PbS)ₓ(SnTe)₁₋ₓ: A=20:0 (x=1), 15:5 (x=0.74), B=10:10 (x=0.49), C=5:15 (x=0.24), E=0:20 (x=0). Crystalline peaks are due to: PbS in A, SnTe in E, and a mix of two solid solutions in diffractograms B through D. The broad diffuse scattering maxima near 20° 20 are due to quartz discs supporting the films. Crystalline phases in all intermediate materials are a mix of two cubic (PbₓSn₁₋ₓ)(SₓTe₁₋ₓ) phases. The first of the two solid solution phases, richest in PbS, is apparent in B, with a likely formula of (Pb_{0.8}Sn_{0.2})(S_{0.8}Te_{0.2}) based on equilibrium phase relationships. This phase is difficult to discern when the PbS precursor was added in lesser amounts (C and D). The second solid solution phase, richest in SnTe, is apparent in the C and D diffractograms, with a likely formula of (Sn_{0.7}Pb_{0.3})(Te_{0.7}S_{0.3}), again based on equilibrium phase relationships. Traces of elemental Te are present in C-E.

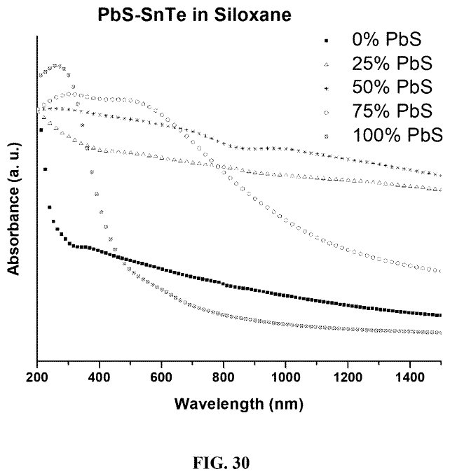

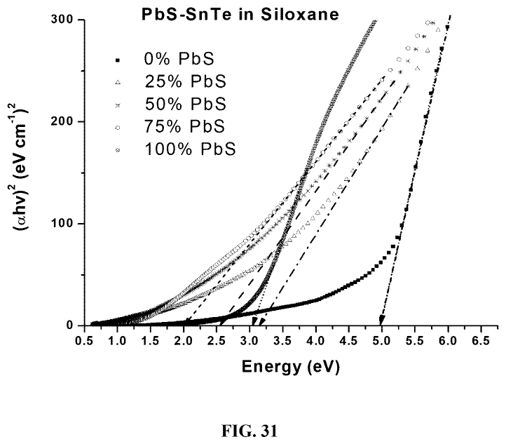

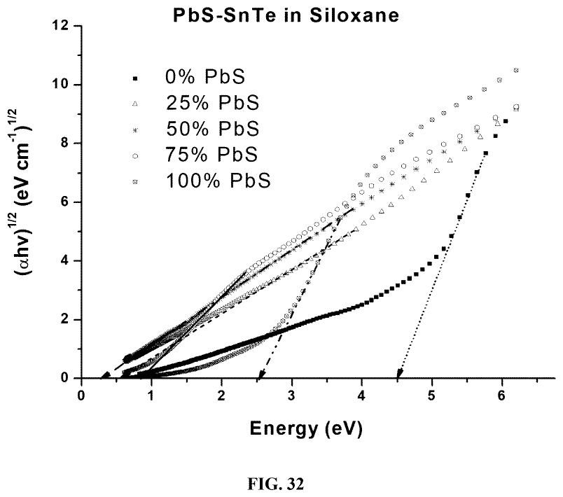

FIG. 30 shows the UV-Vis absorption spectra of the PbS—SnTe/siloxane nanocomposite films at various weight percentages. FIG. 31 shows the direct band gap Tauc plots of PbS—SnTe siloxane nanocomposite films at various weight percentages. Direct band gaps range from 2.0 to 3.15 eV. FIG. 32 shows the indirect band gap Tauc plots of PbS—SnTe/siloxane nanocomposite films at various percentages. Intermediate compositions show indirect band gaps between 0.28 eV and 0.85 eV.

The particle sizes of the intermediate compositions of compound semiconductor phases in the nanocomposites were determined using powder XRD and ranged from 1.1 nm to 11.8 nm for different weight percentages of the metal chalcogenides. These sizes are considerably smaller than those of the pure (Bn₂SnTe)₃/siloxane based nanocomposite, which showed SnTe nanoparticles ranging from 51 to 93 nm. The optical gaps of the thin film quantum dots (QDs) are wider than those of bulk samples due to quantum confinement effects. This effect causes PbS—SnTe thin films of intermediate compositions to have optical gap values in the Vis-NIR region, ranging from 2 to 0.85 eV. Their bulk material counterparts typically have an optical gap of 0.18 eV, in the IR range. These results show that particle sizes in the (Bn₂SnTe)₃/siloxane-based nanocomposites can be further reduced to quantum dot sizes and controlled by the addition of Pb(SBn)₂.

### Example 8—Synthesis and Characterization of Quaternary PbS—SnTe Siloxane Polymer-Based Nanocomposites with Varying Formation Temperatures

Organometallic single source precursors Pb(SBn)₂ and (Bn₂SnTe)₃ and a siloxane polymer were prepared similarly to the methods described in Examples 1 and 2. An aliquot of 20 mg polymer was stirred with 1.5 mL of pyridine for 30 min in a vial to dissolve. In another vial, 10 mg each of (Bn₂SnTe)₃ and Pb(SBn)₂ organometallic single source precursors with various weight percentages were dissolved in pyridine and stirred for 10 min. Once dissolved, the solutions of organometallic precursors and siloxane were mixed and stirred together for an additional 15 min.

Quartz discs 15 mm in diameter and 1.5 mm thick were rinsed with acetone and DI water. Solutions were added dropwise onto the discs and spin cast for 10 sec at 1,000 RPM and an additional 20 sec at 2,500 RPM. To increase the amount of material available for strong XRD diffraction signals without producing films too opaque for optical measurements, additional drops were added to the spin cast films and the solvent was allowed to evaporate.

The quartz discs coated with cast films were placed onto quartz slides. The slides and discs were inserted into a tube furnace. A purge of nitrogen was passed through the furnace for 5 min at 8 scfm. The nitrogen flow was reduced to a minimal flow observed as 1-2 bubbles per second in an exhaust bubbler and heating was started. The furnace temperature was ramped to the various target temperatures over 30 min, followed by holding for 30 min, then returning to 30° C. before collecting X-ray diffractograms and optical data. The effects of variation of precursor weight compositions in the nanocomposites on nanoparticle size and optical properties were studied using powder X-ray diffraction and UV-Vis absorption spectroscopy techniques respectively.

The nanocomposites were heated at temperatures of 150° C., 200° C., 250° C., and 300° C. The effects of increasing annealing temperature of nanocomposites on nanoparticle size and optical properties were studied by powder X-ray diffraction and UV-Vis absorption spectroscopy.

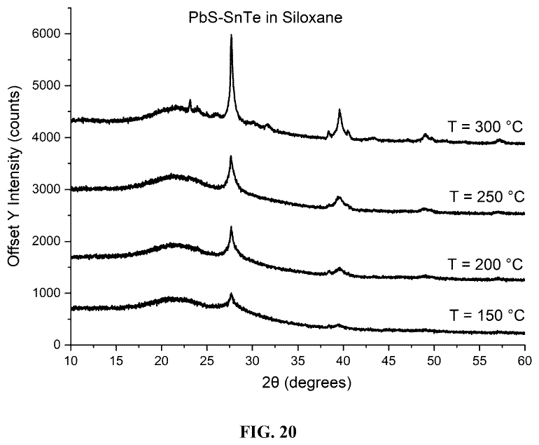

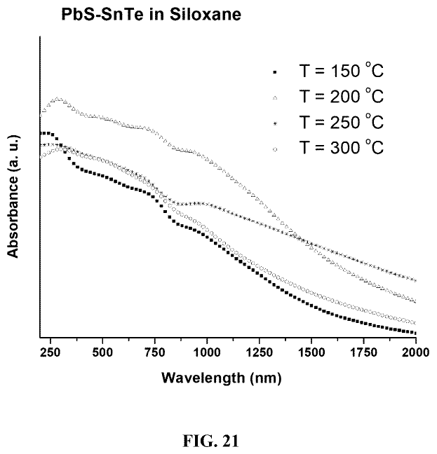

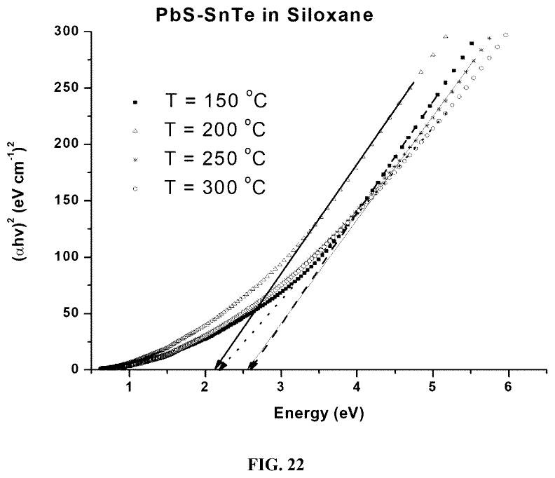

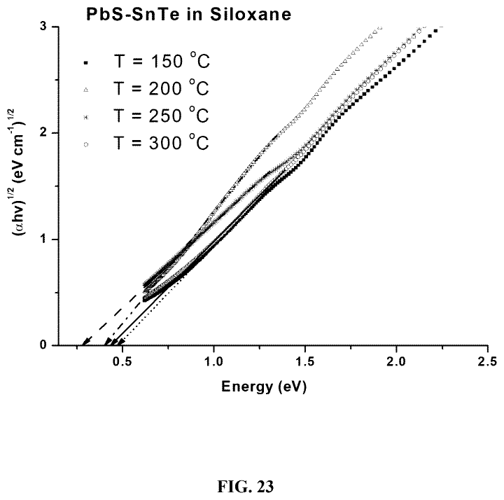

Powder XRD diffractograms are shown in FIG. 20. Two cubic (PbₓSn₁₋ₓ)(S₁₋ₓTeₓ) phases are present in each intermediate composition, with the PbS-rich phase being difficult to discern below 300° C. due to low concentration and large peak broadening. Traces of elemental Te are present in all patterns. The broad diffuse scattering maxima near 20° 20 are due to the quartz discs supporting the films. FIG. 21 shows the UV-Vis absorption spectra of the PbS—SnTe/siloxane nanocomposite films at various temperatures. FIG. 22 shows the direct band gap Tauc plots of the PbS—SnTe/siloxane nanocomposite films at various temperatures. FIG. 23 shows the indirect band gap Tauc plots of the PbS—SnTe/siloxane nanocomposite films at various temperatures.

The particle sizes of the PbS—SnTe quantum dots in the nanocomposites were determined using powder XRD and ranged from 1.3 nm to 11.8 nm at different temperatures. The optical gap of thin film quantum dots is wider than that of bulk samples due to the quantum confinement effect. This effect causes PbS—SnTe thin films to have absorption in the Vis-NIR region, with optical gap values for the intermediate compositions ranging from 0.28 to 2.6 eV. These results show that the particle size of SnTe in the (Bn₂SnTe)₃/siloxane-derived nanocomposites can be further reduced and controlled by the addition of Pb(SBn)₂ prior to pyrolysis, and that a broad temperature range is available for the preparation of quantum dots.

### Example 9—Synthesis and Characterization of SnSe co-pyrolyzed with cyclohexasilane

Organometallic single source precursor (Bn2SnSe)3 was prepared according to procedures in Example 2. Dodecahydrocyclohexasilane (CHS, Si6H12) was prepared using a modification of the synthetic procedure in Choi, S—B., Kim, B-K., Boudjouk, P., Grier, D. G. J. Am. Chem. Soc. 2001, 123, 8117-8118 and Elangovan, A., Anderson, K., Boudjouk, P., Schulz, D. L., U.S. Pat. No. 8,975,429 B2, Mar. 10, 2015.

A 630 mg (0.553 mmol) aliquot of (Bn₂SnSe)₃ was dissolved in 10 mL of dichloromethane in a 20 mL vial, producing a clear solution. The vial was transferred to a glovebox. CHS was added dropwise and stirred at room temperature. After 1.5 hours, the solution turned pinkish red. Several drops of the solution were drop cast onto a quartz disc of 15 mm diameter and 1.5 mm thickness. The solvent was allowed to dry, and the resulting film on the disc was transferred under a nitrogen blanket into a BTS 500 chamber built for in situ heating in an X-ray diffractometer.

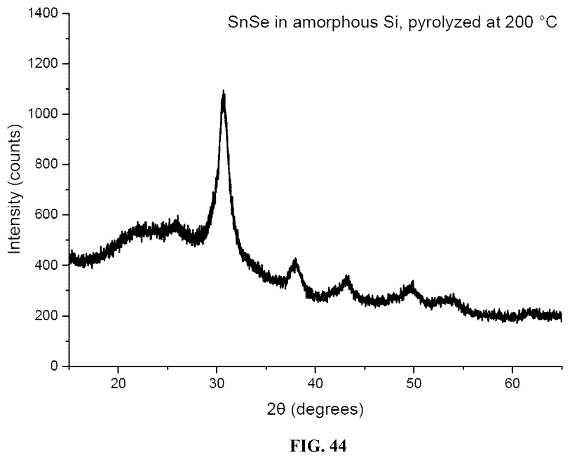

Following heating to 200 degrees C. and subsequent cooling to room temperature, a diffractogram was collected as shown in FIG. 44 to determine the crystalline components present. Phase pure orthorhombic SnSe was observed by powder XRD, with a crystallite size of 9.4 nm, as determined using the Scherrer equation. The heated CHS did not produce a crystalline matrix.

### Example 10—Summary of Example Embodiments

Based on the foregoing examples, certain embodiments described herein are summarized in Table 1. Table 1 shows the pyrolysis temperature, XRD particle size, and direct and indirect band gap energies.

TABLE 1

| | Temp | XRD Size, | Direct Eg/d | Indirect Eg/id |
|---|---|---|---|---|
| Embodiments | ° C. | nm | (eV) | (eV) |
| Binaries | | | | |
| PbS | 150 | 4.2 | 2.66 | 2.37 |
| | 200 | 5.8 | 2.64 | 2.24 |
| | 250 | 8.1 | 2.03 | 1.38 |
| | 350 | 10.9 | 1.60 | 1.29 |
| SnS | 250 | 35 | 2.93 | 2.17 |
| | 300 | 32 | 3.04 | 2.35 |
| SnSe | 150 | 7.5 | 2.71 | 1.94 |
| | 200 | 10.1 | 3.78 | 2.17 |
| | 250 | 9.3 | 4.19 | 2.65 |
| | 300 | 9.6 | 4.26 | 2.5 |
| SnTe | 120 | 80 | 4.92 | 3.44 |
| | 150 | 89 | 5.17 | 4.6 |
| | 200 | 74 | 4.97 | 4.33 |
| | 250 | 63 | 4.97 | 4.5 |
| | 300 | 53 | 5.00 | 4.42 |
| CdS | 250 | 1.6 | 2.85 | 2.68 |
| | 300 | 2 | 2.65 | 2.5 |
| Ternaries | | | | |
| Sn(Sx, Sel-x) | | | | |
| x = 0.0 (SnSe) | 250 | 9.3 | 4.19 | 2.65 |
| x = 0.25 | 250 | 11.8 | 2.69 | 2.46 |
| x = 0.5 | 250 | 10.9 | 2.54 | 2.2 |
| x = 0.75 | 250 | 11.3 | 2.44 | 2.05 |
| x = 1.0 (SnS) | 250 | 35 | 2.93 | 2.17 |
| PbSx-SnS1-x | | | | |
| x = 0.0 (SnS): orth | 250 | 35 | 2.93 | 2.17 |
| x = 0.25: cubic | 250 | 6.3 | 2.5 | 1.38 |
| x = 0.25: orth | 250 | 194 | 2.5 | 1.38 |
| x = 0.5: cubic | 250 | 5.7 | 1.87 | 0.46 |
| x = 0.5: orth | 250 | 412 | 1.87 | 0.46 |
| x = 0.75: cubic | 250 | 19.2 | 2.18 | 0.27 |
| x = 0.75: orth | 250 | 8.1 | 2.18 | 0.27 |
| x = 1.0 (PbS): cubic | 250 | 8.1 | 2.03 | 1.38 |
| PbSx-CdS1-x | | | | |
| x = 0.0 (CdS): hexag | 250 | 1.6 | 2.85 | 2.68 |
| x = 0.25: cubic | 250 | 35 | 2.71 | 2.06 |
| x = 0.25: hexag | 250 | 2 | 2.71 | 2.06 |
| x = 0.5: cubic | 250 | 34 | 2.04 | 1.32 |
| x = 0.5: hexag | 250 | 1.4 | 2.04 | 1.32 |
| x = 0.75: cubic | 250 | 18.5 | 2.03 | 1.16 |
| x = 0.75: hexag | 250 | 1.7 | 2.03 | 1.16 |
| x = 1.0 (PbS): cubic | 250 | 8.1 | 2.03 | 1.38 |
| Quaternary | | | | |
| SnTex-PbS1-x: comp | | | | |
| x = 0.0 (PbS) | 250 | 8.1 | 2.03 | 1.38 |
| x = 0.25: phase1 | 250 | 7.4 | 2 | 0.85 |
| x = 0.25: phase2 | 250 | 9.7 | 2 | 0.85 |
| x = 0.5: phase1 | 250 | 1.6 | 2.56 | 0.28 |
| x = 0.5: phase2 | 250 | 11.8 | 2.56 | 0.28 |
| x = 0.75: phase1 | 250 | 1.1 | 3.15 | 0.56 |
| x = 0.75: phase2 | 250 | 7.4 | 3.15 | 0.56 |
| x = 1.0 (SnTe) | 250 | 63 | 4.97 | 4.5 |
| SnTe0.5-PbS0.5: temp | | | | |
| phase1 | 150 | 1.7 | 2.6 | 0.48 |
| phase2 | 150 | 4.5 | 2.6 | 0.48 |
| phase1 | 200 | 4.7 | 2.13 | 0.4 |
| phase2 | 200 | 6.7 | 2.13 | 0.4 |
| phase1 | 250 | 1.6 | 2.56 | 0.28 |
| phase2 | 250 | 11.8 | 2.56 | 0.28 |
| phase1 | 300 | 1.3 | 2.2 | 0.44 |
| phase2 | 300 | 11.0 | 2.2 | 0.44 |

The disclosures being thus described, it will be obvious that the same may be varied in many ways. Such variations are not to be regarded as a departure from the spirit and scope of the disclosures and all such modifications are intended to be included within the scope of the following claims. The above specification provides a description of the manufacture and use of the disclosed compositions and methods. Since many embodiments can be made without departing from the spirit and scope of the disclosure, the invention resides in the claims.

The present disclosure is further defined by the following numbered embodiments.

Embodiment 1: A method of forming a nanocomposite of semiconducting nanoparticles and polymer, the method comprising: combining into a substantially homogenous solution at least one organometallic precursor and at least one matrix precursor; and thermolyzing the solution forming a nanocomposite of semiconducting nanoparticles and a matrix.

2. The method of embodiment 1, wherein the matrix precursor comprises a polyheterocycle, a siloxane, a polypropylene, a polyethylene, a polyaniline, a polyphenylene, a polyacetylene, a polystyrene, an acrylate, a polyphenol, an epoxide, a peptide, a polypeptide, a peptoid, a cellulose, a silicon, a graphene, or a combination or mixture thereof.

3. The method of any one of embodiments 1-2, wherein the organometallic precursor comprises a metal chalcogenide precursor.

4. The method of any one of embodiments 1-3, wherein the method comprises dissolving the organometallic precursor in a solvent prior to combining with the matrix precursor.

5. The method of any one of embodiments 1-4, wherein the method comprises dissolving the matrix polymeric precursor in a solvent prior to combining with the organometallic precursor.

6. The method of embodiment 4 or 5, wherein the solvent comprises an aqueous solvent, organic solvent, or mixture thereof.

7. The method of any one of embodiments 1-6, wherein the organometallic precursor comprises a phenyl, a benzyl, a benzhydryl, a trityl, an allyl, a hydryl, an alkyl an alkenyl, and/or an araalkenyl group.

8. The method of any one of embodiments 1-7, wherein the organometallic precursor comprises (Bn₂GeSe)₃, Bn₃Bi, Bn₃Sb, Bn₃In, (PhSe)₂Pb, (BnS)₃Bi, Pb(SBn)₂, (Bn₂SnS)₃, (Bn₂SnSe)₃, (Bn₂SnTe)₃, Cd(SBn)₂, (Bn₂GeS)₃, BnLi, BnNa, BnK, BnRb, BnCs, Bn₂Be, Bn₂Mg, Bn₂Ca, Bn₂Sr, Bn₂Ba, Bn₃B, Bn₃Al, Bn₃Ga, Bn₄Si, Bn₄Ge, Bn₄Sn, Bn₄Pb, Bn₃As, Bn₄Ti, Bn₄Zr, Bn₄Hf, Bn₄V, Bn₅Ta, Bn₆Mo2, Bn₆W₂, Bn₄Mo, Bn₄W, Bn₂Zn, Bn₂Hg, Bn₄Th, Bn₂SnX₃ ⁻M⁺, where X=a halide and M⁺=an alkali metal, or a mixture thereof.

9. The method of any one of embodiments 1-8, wherein the matrix precursor comprises mercaptopropylmethylpolysiloxane, benzylmercaptopropylmethylpolysiloxane, or a combination thereof.

10. The method of any one of embodiments 1-9, wherein the thermolyzing comprises a temperature of about 120° C. to about 350° C. for at least about 30 min holding time.

11. The method of any one of embodiments 1-10, wherein the organometallic precursor comprises Pb(SBn)₂, and the thermolyzing is at a temperature of about 150° C. to about 350° C.

12. The method of any one of embodiments 1-10, wherein the organometallic precursor comprises (Bn₂SnS)₃, and the thermolyzing is at a temperature of about 200° C. to about 300° C.

13. The method of any one of embodiments 1-10, wherein the organometallic precursor comprises (Bn₂SnSe)₃, and the thermolyzing is at a temperature of about 200° C. to about 300° C.

14. The method of any one of embodiments 1-10, wherein the organometallic precursor comprises (Bn₂SnTe)₃, and the thermolyzing is at a temperature of about 120° C. to about 300° C.

15. The method of any one of embodiments 1-10, wherein the organometallic precursor comprises Cd(SBn)₂, and the thermolyzing is at a temperature of about 250° C. to about 300° C.

16. The method of any one of embodiments 1-10, wherein the method comprises two organometallic precursors comprising (Bn₂SnS)₃ and (Bn₂SnSe)₃.

17. The method of embodiment 16, wherein the organometallic precursors are in a molar ratio of (Bn₂SnS)₃ to (Bn₂SnSe)₃ of from about 0:1 to about 1:0.

18. The method of any one of embodiments 1-10, wherein the method comprises two organometallic precursors comprising Pb(SBn)₂ and (Bn₂SnS)₃.

19. The method of embodiment 18, wherein the organometallic precursors are in a molar ratio of Pb(SBn)₂ to (Bn₂SnS)₃ of from about 0:1 to about 1:0.

20. The method of any one of embodiments 1-10, wherein the method comprises two organometallic precursors comprising Pb(SBn)₂ and Cd(SBn)₂.

21. The method of embodiment 20, wherein the organometallic precursors are in a molar ratio of Pb(SBn)₂ to Cd(SBn)₂ of from about 0:1 to about 1:0.

22. The method of any one of embodiments 1-10, wherein the method comprises two organometallic precursors comprising Pb(SBn)₂ and (Bn₂SnTe)₃.

23. The method of embodiment 22, wherein the organometallic precursors are in a weight ratio of Pb(SBn)₂ to (Bn₂SnTe)₃ of from about 0:1 to about 1:0.

24. The method of any one of embodiments 16-23, wherein the organometallic precursors are dissolved together in a solvent prior to combining with the polymer precursor.

25. The method of any one of embodiments 1-24, wherein the nanoparticles have a tailored direct band gap energy between about 0.27 and about 5.17 Eg/d (eV).

26. The method of any one of embodiments 1-25, wherein the nanoparticles have a tailored size of less than about 500 nm as measured by x-ray diffraction.

27. The method of any one of embodiments 1-25, wherein the nanoparticles have a tailored size of less than the Bohr radii of the nanoparticles' constituents as measured by x-ray diffraction.

28. The method of any one of embodiments 25-27, wherein the direct band gap energy and/or nanoparticle size is tailored by selecting a temperature for thermolysis; wherein the temperature for thermolysis is between about 120° C. and about 300° C.

30. The method of any one of embodiments 1-29, wherein the matrix precursor comprises one or more functional side-groups.

31. A nanocomposite comprising: a matrix and nanoparticles dispersed throughout the matrix; wherein the nanoparticles comprise an alkali or alkaline earth metal, a metalloid, transition metal, post-transition metal, a main group element, or combination thereof.

32. The nanocomposite of embodiment 31, wherein the nanoparticles are uniformly dispersed.

33. The nanocomposite of any one of embodiments 31-32, wherein the quantum dots comprise one or more of the following Li, Na, K, Rb, Cs, Be, Mg, Ca, Sr, Ba, Ti, Zr, Hf, V, Mo, W, Zn, Hg, Th, B, Al, Ga, Si, Ge, Sn, Pb, As, Bi, Cd, Cu, In, P, S, Sb, Se, Te, GeS, GeSe, GeTe, SnS, SnSe, SnTe, PbS, PbSe, PbTe, CdS, CdSe, CdTe, ZnS, ZnSe, ZnTe, InP, InAs, GaAs, Bi₂S₃, Bi₂Se₃, Bi₂Te₃, Sb₂S₃, Sb₂Se₃, Sb₂Te₃, CuInSe₂, inorganic perovskites of the formulas ABX₃, A₂BX₆, A₂M^{I}M^{III}X₆, A₂M^{I}M^{III}X₈, A₂YX, A₃BX₆ or A₃B₂X₉ where A=Cs, Rb, K, and/or a lanthanide, B/M^{I}M^{III}=Pb, Sn, Mn, Fe, Co, Ni, Zn, Bi, Sb, Mo, W, Ru, Rh, Cu, Ag, and/or B, X═O, S, Se, Te, F, Cl, Br, and/or I, Y=S, Se, and/or Te, with or without doping of transition metals such as Mn, Co, Fe, and/or Ni, a combination thereof and/or a solid solution of the foregoing.

34. The nanocomposite of any one of embodiments 31-33, wherein the nanoparticles have an average diameter of between about 1.1 nm and about 100 nm as measured by x-ray diffraction.

35. The nanocomposite of any one of embodiments 31-34, wherein the matrix comprises a polymer, a copolymer, a terpolymer, or a combination thereof formed from a matrix precursor comprising a polyheterocycle, a siloxane, a polypropylene, a polyethylene, a polyaniline, a polyphenylene, a polyacetylene, a polystyrene, an acrylate, a polyphenol, an epoxide, a peptide, a polypeptide, a peptoid, a cellulose, a silicon, a graphene, or a combination or mixture thereof.

36. The nanocomposite of embodiment 35, wherein the matrix precursor further comprises an inorganic material, a functional side-group, or a mixture thereof.

38. The nanocomposite of embodiment 36 or 37, wherein the functional side-group comprises one or more of a thiol, a phosphine, an alkyl, an alkene, a carboxylic acid, an aromatic group, a hetero-atom cyclic group, a TOPO, oleic acid, an ether, an ester, or a combination thereof.

39. The nanocomposite prepared by the process of any one of embodiments 1-30.

40. Use of the nanocomposite of any one of embodiments 31-38 in an electronic device.

41. Use of the nanocomposite of embodiment 40, wherein the electronic device is a phone, a tablet, a computer, a wearable, a sensor, a chip, an electronic display, a solar cell, a battery, an electronic printing device, an energy storage device, an energy production material, a magnetoelectronic device, a magnetic device, a photovoltaic device, or a quantum dot solar cell (QDSC).

The disclosure is not to be limited to the particular embodiments described herein. The previous detailed description is of a small number of embodiments for implementing the disclosure and is not intended to be limiting in scope. The following claims set forth a number of the embodiments of the disclosure with greater particularity.

What is claimed is:

1. A method of forming a nanocomposite of semiconducting nanoparticles and matrix, the method comprising:
combining into a substantially homogenous solution at least one organometallic precursor and at least one matrix precursor; whreein the organometallic precursor comprises (Bn₂GeSe)₃, Bn₃Bi, Bn₃Sb, Bn₃In, (PhSe)₂Pb, (BnS)₃Bi, Pb(SBn)₂, (Bn₂SnS)₃, (Bn₂SnSe)₃, (Bn₂SnTe)₃, (Bn₂GeS)₃, (Bn₂GeTe)₂, Bn₂SnCl₂, BnLi, BnNa, BnK, BnRb, BnCs, Bn₂Be, Bn₂Mg, Bn₂Ca, Bn₂Sr, Bn₂Ba, Bn₃B, Bn₃Al, Bn₃Ga, Bn₄Si, Bn₄Ge, Bn₄Sn, Bn₄Pb, Bn₃As, Bn₄Ti, Bn₄Zr, Bn₄Hf, Bn₄V, Bn₅Ta, Bn₆Mo2, Bn₆W₂, Bn₄Mo, Bn₄W, Bn₂Zn, Bn₂Hg, Bn₄Th, Bn₂SnX₃ ⁻M⁺, where X=a halide and M⁺=an alkali metal, or a mixture thereof; and
thermolyzing the solution forming a nanocomposite of semiconducting nanoparticles and a matrix.

2. The method of claim 1, wherein the matrix precursor comprises a polyheterocycle, a siloxane, a polypropylene, a polyethylene, a polyaniline, a polyphenylene, a polyacetylene, a polystyrene, an acrylate, a polyphenol, an epoxide, a peptide, a polypeptide, a peptoid, a cellulose, a silane, a graphene, or a combination or mixture thereof.

3. The method of claim 1, wherein the organometallic precursor comprises a nanoparticle precursor.

4. The method of claim 1, wherein the method comprises dissolving the organometallic precursor and/or the matrix precursor in a solvent prior to the combining.

5. The method of claim 1, wherein the organometallic precursor comprises (Bn₂GeSe)₃, Bn₃Bi, Bn₃Sb, Bn₃In, (Bn₂SnS)₃, (Bn₂SnSe)₃, (Bn₂SnTe)₃, (Bn₂GeS)₃, (Bn₂GeTe)₂, Bn₂SnCl₂, BnLi, BnNa, BnK, BnRb, BnCs, Bn₂Be, Bn₂Mg, Bn₂Ca, Bn₂Sr, Bn₂Ba, Bn₃B, Bn₃Al, Bn₃Ga, Bn₄Si, Bn₄Ge, Bn₄Sn, Bn₄Pb, Bn₃As, Bn₄Ti, Bn₄Zr, Bn₄Hf, Bn₄V, Bn₅Ta, Bn₆Mo₂, Bn₆W₂, Bn₄Mo, Bn₄W, Bn₂Zn, Bn₂Hg, Bn₄Th, Bn₂SnX₃⁻M⁺, where X=a halide and M⁺=an alkali metal, or a mixture thereof.

6. The method of claim 1, wherein the matrix precursor comprises mercaptopropylmethylpolysiloxane, benzylmercaptopropylmethylpolysiloxane, or a combination thereof.

7. The method of claim 1, wherein the thermolyzing comprises a temperature of about 120° C. to about 350° C. for at least about 30 min holding time.

8. The method of claim 1, wherein the organometallic precursor comprises Pb(SBn)₂ and the thermolyzing is at a temperature of about 150° C. to about 350° C., wherein the organometallic precursor comprises (Bn₂SnS)₃ and the thermolyzing is at a temperature of about 200° C. to about 300° C., or wherein the organometallic precursor comprises (Bn₂SnTe)₃ and the thermolyzing is at a temperature of about 120° C. to about 300° C.

9. The method claim 1, wherein the method comprises two organometallic precursors comprising (Bn₂SnS)₃ and (Bn₂SnSe)₃.

10. The method of claim 1, wherein the organometallic precursors comprise Pb(SBn)₂ and at least one of (Bn₂SnS)₃, Cd(SBn)₂, and (Bn₂SnTe)₃.

11. The method of claim 1, wherein the nanoparticles have a tailored direct band gap energy between about 0.27 and about 5.17 Eg/d (eV) and/or a tailored size of less than about 500 nm as measured by x-ray diffraction, wherein the direct band gap energy and/or nanoparticle size is tailored by selecting a temperature for thermolysis; wherein the temperature for thermolysis is between about 120° C. and about 300° C.

12. The method of claim 1, wherein the nanoparticles have a tailored size of less than the Bohr radii of the nanoparticles' constituents as measured by x-ray diffraction.

13. The method of claim 1, wherein the matrix precursor comprises one or more functional side-groups.

14. A nanocomposite comprising:
a matrix and nanoparticles dispersed throughout the matrix; wherein the nanoparticles comprise an alkali or alkaline earth metal, a metalloid, transition metal, post-transition metal, a main group element, or combination thereof.

15. The nanocomposite of claim 14, wherein the nanoparticles are uniformly dispersed.

16. The nanocomposite of claim 14, wherein the nanoparticles comprise one or more of the following Li, Na, K, Rb, Cs, Be, Mg, Ca, Sr, Ba, Ti, Zr, Hf, V, Mo, W, Zn, Hg, Th, B, Al, Ga, Si, Ge, Sn, Pb, As, Bi, Cd, Cu, In, P, S, Sb, Se, Te, GeS, GeSe, GeTe, SnS, SnSe, SnTe, PbS, PbSe, PbTe, CdSe, CdTe, ZnS, ZnSe, ZnTe, InP, InAs, GaAs, Bi₂S₃, Bi₂Se₃, Bi₂Te₃, Sb₂S₃, Sb₂Se₃, Sb₂Te₃, CuInSe₂, inorganic perovskites of the formulas ABX₃, A₂BX₆, A₂M^{I}M^{III}X₆, A₂M^{I}M^{III}X₈, A₂YX, A₃BX₆ or A₃B₂X₉ where A=Cs, Rb, K, and/or a lanthanide, B/M^{I}M^{III}=Pb, Sn, Mn, Fe, Co, Ni, Zn, Bi, Sb, Mo, W, Ru, Rh, Cu, Ag, and/or B, X=O, S, Se, Te, F, Cl, Br, and/or I, Y=S, Se, and/or Te, with or without doping of transition metals such as Mn, Co, Fe, and/or Ni, a combination thereof and/or a solid solution of the foregoing.

17. The nanocomposite of claim 14, wherein the nanoparticles have an average diameter of between about 1.1 nm and about 100 nm as measured by x-ray diffraction.

18. The nanocomposite of claim 14, wherein the matrix comprises a polymer, a copolymer, a terpolymer, or a combination thereof formed from a matrix precursor comprising a polyheterocycle, a siloxane, a polypropylene, a polyethylene, a polyaniline, a polyphenylene, a polyacetylene, a polystyrene, an acrylate, a polyphenol, an epoxide, a peptide, a polypeptide, a peptoid, a cellulose, a silane, a graphene, or a combination or mixture thereof.

19. The nanocomposite of claim 18, wherein the matrix precursor further comprises an inorganic material, a functional side-group, or a mixture thereof.

20. The nanocomposite of claim 19, wherein the functional side-group comprises one or more of a thiol, a phosphine, an alkyl, an alkene, a carboxylic acid, an aromatic group, a hetero-atom cyclic group, a TOPO, oleic acid, an ether, an ester, or a combination thereof.
